(19) United States
(12) Patent Application Publication
(10) Pub. No.: US 2025/0143107 A1
(43) Pub. Date: May 1, 2025

(54) DISPLAY DEVICE

(71) Applicant: Samsung Display Co., LTD., Yongin-si (KR)

(72) Inventors: Joon Yong PARK, Yongin-si (KR); Sam Tae JEONG, Yongin-si (KR); Yung Bin CHUNG, Yongin-si (KR)

(21) Appl. No.: 18/676,411

(22) Filed: May 28, 2024

(30) Foreign Application Priority Data
Oct. 30, 2023 (KR) 10-2023-0146643

(51) Int. Cl. H10K 59/131

(52) U.S. Cl. CPC H10K 59/131

(57) ABSTRACT

Provided is a display device. A display device includes a substrate, a first conductive layer above the substrate, an active layer above the first conductive layer, a second conductive layer above the active layer, and including a transparent conductive oxide while not including indium (In), a third conductive layer above the second conductive layer, a transistor including a gate electrode at the second conductive layer, and a drain electrode and a source electrode at the active layer, and a light-emitting element including a first electrode at the third conductive layer and connected to the source electrode.

### CROSS REFERENCE TO RELATED APPLICATION

The present application claims priority to, and the benefit of, Korean Patent Application No. 10-2023-0146643, filed on Oct. 30, 2023, in the Korean Intellectual Property Office, the entire disclosure of which is incorporated herein by reference.

### BACKGROUND

### 1. Field

The present disclosure relates to a display device.

### 2. Description of the Related Art

Display devices are becoming increasingly important with the development of multimedia. Accordingly, various display devices such as liquid crystal display devices (LCDs) and organic light-emitting diode display devices (OLEDs) are being developed.

Of the display devices, a self-light-emitting display device includes a self-light-emitting element such as an organic light-emitting diode. The self-light-emitting element may include two electrodes facing each other and a light-emitting layer interposed between the two electrodes. If the self-light-emitting element is an organic light-emitting diode, electrons and holes provided from the two electrodes may be recombined in the light-emitting layer to generate excitons. As the generated excitons change from an excited state to a ground state, light may be emitted.

Because self-light-emitting display devices do not need a light source such as a backlight unit, they are low in power consumption, can be made lightweight and thin, and have a wide viewing angle, high luminance and contrast, and fast response speed. Due to these high-quality characteristics, the self-light-emitting display devices are drawing attention as next-generation display devices.

A self-light-emitting display device may include various circuit layers for driving a light-emitting layer. These circuit layers may be formed through a plurality of patterning processes using masks. As the number of masks and the number of layers constituting a circuit layer decreases, process efficiency can be improved. Accordingly, a height difference between the light-emitting layer and a transistor for driving the light-emitting layer can be reduced.

### SUMMARY

Aspects of the present disclosure provide a display device including a conductive layer with low reflectivity.

Aspects of the present disclosure also provide a display device with reduced or minimized light-induced degradation.

Aspects of the present disclosure also provide a display device with improved reliability.

Aspects of the present disclosure also provide a display device with improved process efficiency.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate, a first conductive layer above the substrate, an active layer above the first conductive layer, a second conductive layer above the active layer, and including a transparent conductive oxide while not including indium (In), a third conductive layer above the second conductive layer, a transistor including a gate electrode at the second conductive layer, and a drain electrode and a source electrode at the active layer, and a light-emitting element including a first electrode at the third conductive layer and connected to the source electrode.

The second conductive layer may include aluminum-zinc-tin-oxide (AZTO).

The second conductive layer may include a first gate conductive layer, and a second gate conductive layer above the first gate conductive layer and having higher light transmittance than the first gate conductive layer.

The second gate conductive layer may include aluminum-zinc-tin-oxide (AZTO).

The second gate conductive layer may include about 1 at % to about 10 at % of aluminum based on atoms excluding oxygen atoms.

The second gate conductive layer may include about 60 at % to about 90 at % of zinc based on atoms excluding oxygen atoms.

The second gate conductive layer may include about 10 at % to about 30 at % of tin based on atoms excluding oxygen atoms.

The second gate conductive layer may include about 0.5 at % to about 5 at % of aluminum based on total atoms.

The second gate conductive layer may include about 20 at % to about 40 at % of zinc based on total atoms.

The second gate conductive layer may include about 7 at % to about 15 at % of tin based on total atoms.

The second gate conductive layer may include about 50 at % to about 60 at % of oxygen based on total atoms.

The first gate conductive layer may have lower reflectivity than the second gate conductive layer.

The first gate conductive layer may include titanium (Ti).

A thickness of the second gate conductive layer may be greater than a thickness of the first gate conductive layer.

The thickness of the second gate conductive layer may be about 2 times to about 30 times the thickness of the first gate conductive layer.

The thickness of the second gate conductive layer may be about 400 Å to about 3000 Å.

The thickness of the first gate conductive layer may be about 100 Å to about 200 Å.

The third conductive layer may include a transparent conductive oxide that is different from the transparent conductive oxide of the second conductive layer.

The second conductive layer may have lower reflectivity than the first conductive layer or the third conductive layer.

According to an aspect of the present disclosure, there is provided a display device including a substrate, a first conductive layer above the substrate, an active layer above the first conductive layer, a second conductive layer above the active layer, and including a first gate conductive layer including a first material including metal, a second gate conductive layer above the first gate conductive layer, and including a second material including metal, a third gate conductive layer above the second gate conductive layer, and including a third material including metal, and a fourth gate conductive layer above the third gate conductive layer, and including aluminum-zinc-tin-oxide (AZTO), a transistor above the first conductive layer, and a light-emitting element above the second conductive layer and connected to the transistor.

The first material, the second material, and the third material may include molybdenum (Mo), aluminum (AI), chromium (Cr), gold (Au), titanium (Ti), nickel (Ni), neodymium (Nd), copper (Cu), or an alloy thereof.

The first material may include titanium (Ti).

The second material may include copper (Cu).

The third material may include titanium (Ti).

A thickness of the fourth gate conductive layer may be greater than a thickness of the third gate conductive layer.

A thickness of the second gate conductive layer may be greater than a thickness of the fourth gate conductive layer.

According to an aspect of the present disclosure, there is provided a display device including a substrate including a display area, and a pad area at a side of the display area, a first conductive layer above the substrate, an active layer above the first conductive layer, a second conductive layer above the active layer, and including transparent conductive oxide, while not including indium (In), at the display area, a transistor above the first conductive layer in the display area, a light-emitting element above the second conductive layer in the display area, and connected to the transistor, and a wiring pad above the substrate in the pad area, and including a first pad electrode at the first conductive layer, and a second pad electrode at the second conductive layer.

The second pad electrode might not include a transparent conductive oxide.

The display device may further include a driving component connected to the wiring pad, wherein the second pad electrode includes a sub-pad layer including metal directly contacting the driving component.

A display device according to one or more embodiments of the present disclosure may include a conductive layer with low reflectivity.

A display device according to one or more embodiments of the present disclosure can reduce or minimize light-induced degradation.

A display device according to one or more embodiments of the present disclosure can have improved reliability.

A display device according to one or more embodiments of the present disclosure can have improved process efficiency.

However, the aspects of the present disclosure are not restricted to the one set forth herein. The above and other aspects of the present disclosure will become more apparent to one of daily skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to one or more embodiments;

FIG. 2 is a cross-sectional view taken along the line X1-X1′ of FIG. 1;

FIG. 3 is a cross-sectional view of a display device according to one or more embodiments;

FIG. 4 is a plan view illustrating a state in which connection films are attached to wiring pads of the display device according to one or more embodiments;

FIG. 5 is a plan view illustrating a state in which the connection films are not attached to the wiring pads of the display device according to one or more embodiments;

FIG. 6 illustrates pixels and lines of the display device according to one or more embodiments;

FIG. 7 is a schematic plan view of a part of a display area of a display substrate according to one or more embodiments;

FIG. 8 is a schematic plan view of a part of a display area of a display substrate according to one or more embodiments;

FIG. 9 is a cross-sectional view taken along the line X2-X2′ of FIG. 7;

FIG. 10 is an equivalent circuit diagram of a pixel according to one or more embodiments;

FIG. 11 is a cross-sectional view of an example of a first transistor of a circuit layer according to one or more embodiments;

FIG. 12 is a cross-sectional view of an example of a second transistor and a third transistor of the circuit layer according to one or more embodiments;

FIG. 13 is a cross-sectional view illustrating an example of a part of a display area and a part of a pad area of the display device according to one or more embodiments;

FIG. 14 is a cross-sectional view of an example of a bottom conductive layer according to one or more embodiments;

FIG. 15 is a cross-sectional view of an example of a gate conductive layer according to one or more embodiments;

FIG. 16 is a cross-sectional view of an example of an anode conductive layer according to one or more embodiments;

FIG. 17 is a cross-sectional view of an example of a conventional gate conductive layer;

FIG. 18 is a photograph showing a precipitated particle formed on a cross section of the conventional gate conductive layer;

FIG. 19 is a cross-sectional view illustrating an example of a part of a display area and a part of a pad area of a display device according to one or more embodiments;

FIG. 20 is a cross-sectional view illustrating a wiring pad and a connection film of the display device according to one or more embodiments;

FIGS. 21, 22, and 23 are schematic perspective views of devices including a display device according to one or more embodiments; and

FIGS. 24 and 25 are schematic perspective views of a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

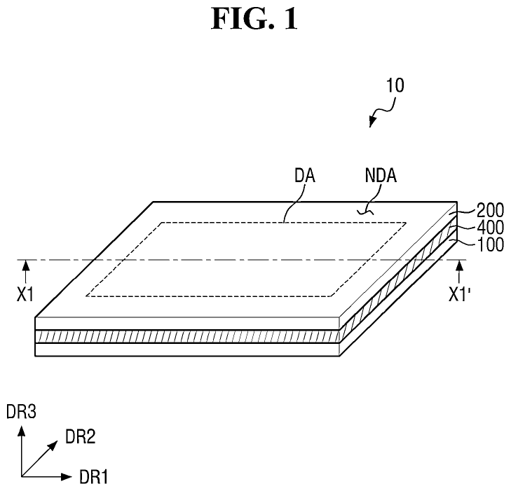

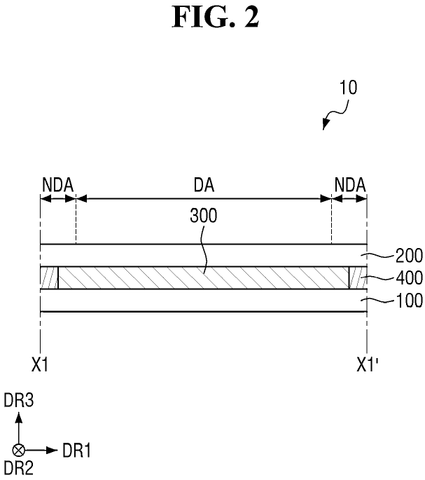

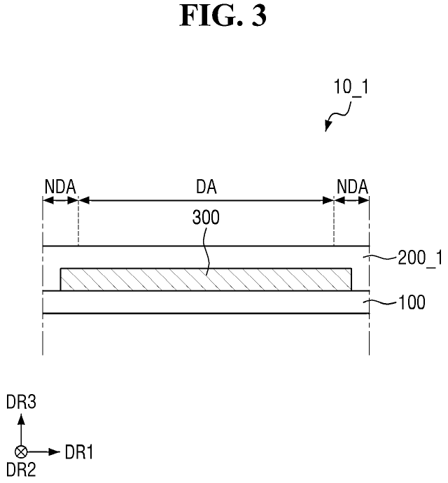

FIG. 1 is a perspective view of a display device 10 according to one or more embodiments. FIG. 2 is a cross-sectional view taken along the line X1-X1′ of FIG. 1. FIG. 3 is a cross-sectional view of a display device 10_1 according to one or more embodiments.

Referring to FIGS. 1, 2, and 3, the display device 10 may be applied to various electronic devices including small and medium-sized electronic equipment, such as tablet personal computers (PCs), smartphones, car navigation units, cameras, center information displays (CIDs) provided in vehicles, wristwatch type electronic devices, personal digital assistants (PDAs), portable multimedia players (PMPs) and game consoles and medium and large-sized electronic equipment, such as televisions, outdoor billboards, monitors, PCs and notebook computers. These are merely presented as examples, and the display device 10 may also be employed in other electronic devices as long as not departing from the spirit of the present disclosure.

In one or more embodiments, the display device 10 may be rectangular in plan view. The display device 10 may include two long sides extending in a first direction DR1, and two short sides extending in a second direction DR2 crossing the first direction DR1. Each corner where a long side of the display device 10 meets a short side may be right-angled. However, the present disclosure is not limited thereto, and each corner may also form a curved surface. In one or more embodiments, the long sides may extend in the second direction DR2, and the short sides may extend in the first direction DR1. The planar shape of the display device 10 is not limited to the above example and may also be a circular shape or other shapes.

In the drawings, the first direction DR1 and the second direction DR2 are horizontal directions crossing each other. For example, the first direction DR1 and the second direction DR2 may be orthogonal to each other. In addition, a third direction DR3 may cross the first direction DR1 and the second direction DR2. For example, the third direction DR3 may be a vertical direction orthogonal to the first direction DR1 and the second direction DR2. Unless otherwise defined, in the present specification, a direction indicated by an arrow of each of the first through third directions DR1 through DR3 may be referred to as one side, and the opposite direction may be referred to as the other side. In addition, in the present specification, “on,” “upper side,” “above,” “top,” and “upper surface” refer to a direction in which the arrow of the third direction DR3 points in the drawings, and “under,” “lower side,” “below,” “bottom,” and “lower surface” refer to a direction opposite to the direction in which the arrow of the third direction DR3 points in the drawings.

The display device 10 may include a display area DA displaying an image and a non-display area NDA not displaying an image. In one or more embodiments, the non-display area NDA may be located around the display area DA and may surround the display area DA.

In one or more embodiments, referring to FIG. 2, the display device 10 may include a display substrate 100, and a color conversion substrate 200 facing the display substrate 100, and may further include a sealing part 400 bonding the display substrate 100 and the color conversion substrate 200 together and a filler 300 filling a space between the display substrate 100 and the color conversion substrate 200.

The display substrate 100 may include elements and circuits for displaying an image, for example, pixel circuits, such as switching elements, a pixel-defining layer defining emission areas and a non-emission area, which will be described later, in the display area DA, and self-light-emitting elements. In one or more embodiments, each of the self-light-emitting elements may include at least one of an organic light-emitting diode, a quantum dot light-emitting diode, an inorganic material-based micro light-emitting diode (e.g., micro LED), or an inorganic material-based nano light-emitting diode (e.g., nano LED). For ease of description, a case where the self-light-emitting elements are organic light-emitting diodes will be described below as an example.

The color conversion substrate 200 may be located on (as used herein, “on” may mean “above”) the display substrate 100, and may face the display substrate 100. In one or more embodiments, the color conversion substrate 200 may include a color conversion pattern that converts the color of incident light. In one or more embodiments, the color conversion pattern may include at least any one of a color filter or a wavelength conversion pattern.

The sealing part 400 may be located between the display substrate 100 and the color conversion substrate 200 in the non-display area NDA. The sealing part 400 may be located along edges of the display substrate 100 and the color conversion substrate 200 in the non-display area NDA to surround the display area DA in plan view. The display substrate 100 and the color conversion substrate 200 may be bonded to each other by the sealing part 400.

In one or more embodiments, the sealing part 400 may be made of an organic material. For example, the sealing part 400 may be made of, but not limited to, epoxy-based resin.

The filler 300 may be located in the space surrounded by the sealing part 400 between the display substrate 100 and the color conversion substrate 200. The filler 300 may fill the space between the display substrate 100 and the color conversion substrate 200.

In one or more embodiments, the filler 300 may be made of a material that can transmit light. In one or more embodiments, the filler 300 may be made of an organic material. For example, the filler 300 may be made of, but not limited to, a silicon-based organic material or an epoxy-based organic material. In one or more embodiments, the filler 300 may also be omitted.

In one or more embodiments, referring to FIG. 3, the display device 10_1 may not include the sealing part 400. For example, a color conversion substrate 200_1 of the display device 10_1 may be an encapsulation substrate. The color conversion substrate 200_1 may include a protruding portion located along the periphery of the color conversion substrate 200_1 and protruding toward a display substrate 100 in the third direction DR3 and a recessed portion surrounded by the protruding portion. The internal space may be sealed by the display substrate 100, the color conversion substrate 200_1, and the protruding portion. A filler 300 may fill the recessed portion.

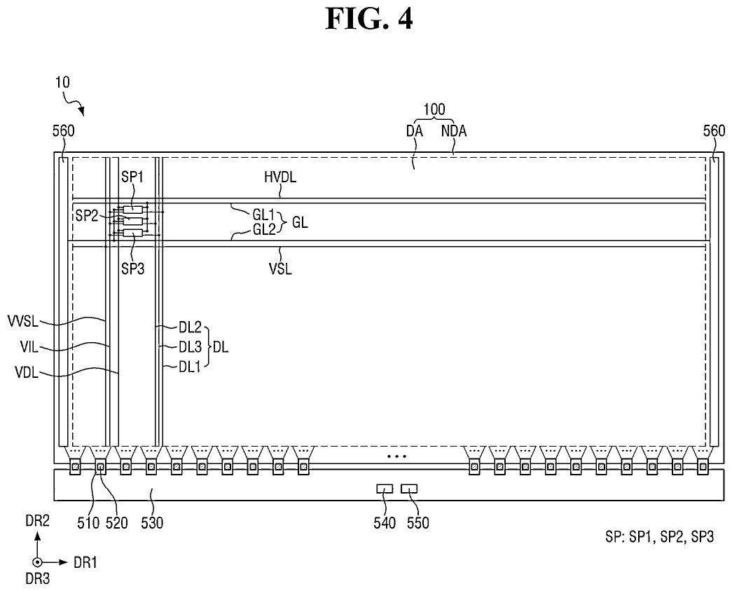

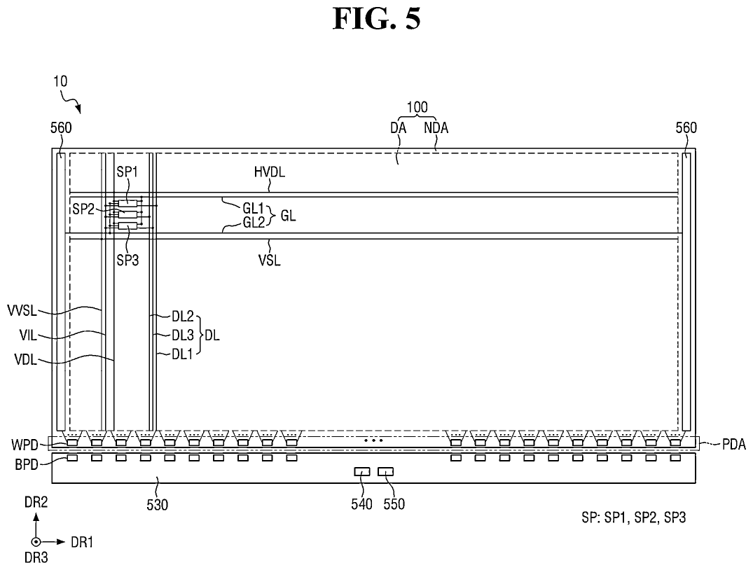

FIG. 4 is a plan view illustrating a state in which connection films 510 are attached to wiring pads WPD of the display device 10 according to one or more embodiments. FIG. 5 is a plan view illustrating a state in which the connection films 510 are not attached to the wiring pads WPD of the display device 10 according to one or more embodiments.

Referring to FIGS. 4 and 5, the display device 10 may include the display substrate 100, the connection films 510, display drivers 520, a circuit board 530, a timing controller 540, a power supply 550, and gate drivers 560.

The display substrate 100 may be rectangular in plan view. For example, the display substrate 100 may be shaped like a rectangular plane having long sides in the first direction DR1 and short sides in the second direction DR2. Each corner where a long side extending in the first direction DR1 meets a short side extending in the second direction DR2 may be right-angled or may be rounded with a curvature (e.g., predetermined curvature). The planar shape of the display substrate 100 is not limited to a rectangular shape, and may also be other polygonal shapes, a circular shape, or an oval shape. For example, the display substrate 100 may be formed flat, but the present disclosure is not limited thereto. For another example, the display substrate 100 may be formed to be bent with a curvature (e.g., predetermined curvature).

The display substrate 100 may include a display area DA and a non-display area NDA.

The display area DA may be an area for displaying an image, and may be defined as a central area of the display substrate 100. In one or more embodiments, the display area DA may include pixels SP, gate lines GL, data lines DL, initialization voltage lines VIL, first voltage lines VDL, horizontal voltage lines HVDL, vertical voltage lines VVSL, and second voltage lines VSL.

The pixels SP may be respectively formed in pixel areas intersected by the data lines DL and the gate lines GL. In one or more embodiments, the pixels SP may include first through third pixels SP1, SP2, and SP3. Each of the first through third pixels SP1, SP2, and SP3 may be connected to a gate line GL and a data line DL. Each of the first through third pixels SP1, SP2, and SP3 may be defined as a minimum unit area that outputs light.

Each of the first through third pixels SP1, SP2, and SP3 may include an organic light-emitting diode including an organic light-emitting layer, a quantum dot light-emitting diode including a quantum dot light-emitting layer, a micro light-emitting diode, or an inorganic light-emitting diode including an inorganic semiconductor.

The first pixels SP1 may emit light of a first color or red light, the second pixels SP2 may emit light of a second color or green light, and the third pixels SP3 may emit light of a third color or blue light. Pixel circuits of the first pixels SP1, pixel circuits of the second pixels SP2, and pixel circuits of the third pixels SP3 may be sequentially arranged in a direction opposite to the second direction DR2, but the order of the pixel circuits is not limited thereto.

The gate lines GL may include first gate lines GL1 and second gate lines GL2. The first gate lines GL1 may extend in the first direction DR1, and may be spaced apart from each other in the second direction DR2. The first gate lines GL1 may receive first gate signals from the gate drivers 560, and may supply the first gate signals to the first through third pixels SP1, SP2, and SP3.

The second gate lines GL2 may extend in the first direction DR1, and may be spaced apart from each other in the second direction DR2. The second gate lines GL2 may receive second gate signals from the gate drivers 560, and may supply the second gate signals to the first through third pixels SP1, SP2, and SP3.

The data lines DL may extend in the second direction DR2, and may be spaced apart from each other in the first direction DR1. The data lines DL may include first through third data lines DL1, DL2, and DL3. The first through third data lines DL1, DL2, and DL3 may supply data voltages to the first through third pixels SP1, SP2, and SP3, respectively.

The initialization voltage lines VIL may extend in the second direction DR2, and may be spaced apart from each other in the first direction DR1. The initialization voltage lines VIL may supply initialization voltages received from the display drivers 520 to the pixel circuits of the first through third pixels SP1, SP2, and SP3. The initialization voltage lines VIL may receive sensing signals from the pixel circuits of the first through third pixels SP1, SP2, and SP3, and may supply the sensing signals to the display drivers 520.

The first voltage lines VDL may extend in the second direction DR2, and may be spaced apart from each other in the first direction DR1. The first voltage lines VDL may supply driving voltages or high potential voltages received from the power supply 550 to the first through third pixels SP1, SP2, and SP3.

The horizontal voltage lines HVDL may extend in the first direction DR1, and may be spaced apart from each other in the second direction DR2. The horizontal voltage lines HVDL may be connected to the first voltage lines VDL. The horizontal voltage lines HVDL may receive driving voltages or high potential voltages from the first voltage lines VDL.

The vertical voltage lines VVSL may extend in the second direction DR2, and may be spaced apart from each other in the first direction DR1. The vertical voltage lines VVSL may be connected to the second voltage lines VSL. The vertical voltage lines VVSL may supply low potential voltages received from the power supply 550 to the second voltage lines VSL.

The second voltage lines VSL may extend in the first direction DR1, and may be spaced apart from each other in the second direction DR2. The second voltage lines VSL may supply low potential voltages to the first through third pixels SP1, SP2, and SP3.

The connection relationship between the pixels SP, the gate lines GL, the data lines DL, the initialization voltage lines VIL, the first voltage lines VDL, the horizontal voltage lines HVDL, the vertical voltage lines VVSL, and the second voltage lines VSL can be variously designed and changed according to the number and arrangement of the pixels SP.

The non-display area NDA may be defined as an area other than the display area DA in the display substrate 100. For example, the non-display area NDA may include fan-out lines connecting the data lines DL, the initialization voltage lines VIL, the first voltage lines VDL, and the vertical voltage lines VVSL to the display drivers 520, and may include the gate drivers 560 and the wiring pads WPD connected to the connection films 510.

Referring to FIG. 5, the non-display area NDA may include a pad area PDA where the wiring pads WPD are located. The pad area PDA may be located adjacent to a side of the display device 10. For example, the pad area PDA may be located adjacent to a lower side of the display device 10. In one or more embodiments, the pad area PDA may extend along the first direction DR1.

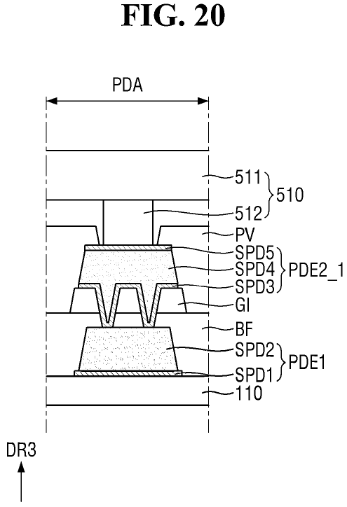

The connection films 510 may be connected to the wiring pads WPD located on a lower side of the non-display area NDA, and to board pads BPD located on an upper side of the circuit board 530. Input terminals (e.g., bumps 512, see FIG. 20) located on one side and the other side of the connection films 510 may be attached to the wiring pads WPD and the board pads BPD by a film attaching process. For example, each of the connection films 510 may be bendable, like a tape carrier package or a chip on film. The connection films 510 may be bent toward the bottom of the display substrate 100 to reduce a bezel area of the display device 10.

The display drivers 520 may be mounted on the connection films 510. For example, the display drivers 520 may be implemented as integrated circuits (ICs). The display drivers 520 may receive digital video data and a data control signal from the timing controller 540, may convert the digital video data into analog data voltages according to the data control signal, and may supply the analog data voltages to the data lines DL through the fan out lines.

The circuit board 530 may support the timing controller 540 and the power supply 550, and may supply signals and power to the display drivers 520. For example, the circuit board 530 may supply signals supplied from the timing controller 540, and may supply power supply voltages supplied from the power supply 550, to the connection films 510 and to the display drivers 520 through the board pads BPD to display an image in each pixel. To this end, signal lines and power lines may be provided on the circuit board 530.

The timing controller 540 may be mounted on the circuit board 530, and may receive image data and a timing synchronization signal from a display driving system or from a graphics device through a user connector provided on the circuit board 530. The timing controller 540 may generate digital video data by arranging the image data according to the pixel arrangement structure based on the timing synchronization signal, and may supply the generated digital video data to the display drivers 520. The timing controller 540 may generate a data control signal and a gate control signal based on the timing synchronization signal. The timing controller 540 may control the data voltage supply timing of the display drivers 520 based on the data control signal, and may control the gate signal supply timing of the gate drivers 560 based on the gate control signal.

The power supply 550 may be located on the circuit board 530 to supply a power supply voltage to the connection films 510 and the display drivers 520. For example, the power supply 550 may generate a driving voltage or a high potential voltage, and may supply the driving voltage or the high potential voltage to the first voltage lines VDL, may generate a low potential voltage, and may supply the low potential voltage to the vertical voltage lines VVSL, and may generate an initialization voltage, and may supply the initialization voltage to the initialization voltage lines VIL.

The gate drivers 560 may be located on at least any one of left or right sides of the non-display area NDA. The gate drivers 560 may generate gate signals based on a gate control signal supplied from the timing controller 540. The gate control signal may include, but is not limited to, a start signal, a clock signal, and a power supply voltage. The gate drivers 560 may supply the gate signals to the gate lines GL according to a set order.

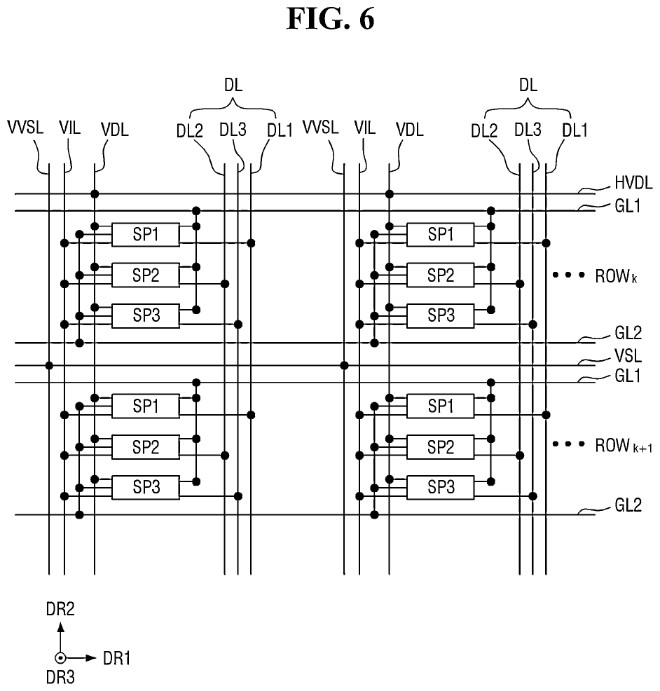

FIG. 6 illustrates pixels and lines of the display device 10 according to one or more embodiments.

Referring to FIG. 6 in addition to FIGS. 4 and 5, the pixels SP may include the first through third pixels SP1, SP2, and SP3. The pixel circuits of the first pixels SP1, the pixel circuits of the second pixels SP2, and the pixel circuits of the third pixels SP3 may be sequentially arranged in the direction opposite to the second direction DR2, but the order of the pixel circuits is not limited thereto.

Each of the first through third pixels SP1, SP2, and SP3 may be connected to a first voltage line VDL, an initialization voltage line VIL, a gate line GL, and a data line DL.

The first voltage lines VDL may extend in the second direction DR2. The first voltage lines VDL may be located on left sides of the pixel circuits of the first through third pixels SP1, SP2, and SP3. The first voltage lines VDL may supply a driving voltage or a high potential voltage to transistors of the first through third pixels SP1, SP2, and SP3.

A horizontal voltage line HVDL may extend in the first direction DR1. The horizontal voltage line HVDL may be located above a first gate line GL1 located in a kth row ROWₖ (where k is a positive integer). The horizontal voltage line HVDL may be connected to the first voltage lines VDL. The horizontal voltage line HVDL may receive driving voltages or high potential voltages from the first voltage lines VDL.

The initialization voltage lines VIL may extend in the second direction DR2. The initialization voltage lines VIL may be located on left sides of vertical auxiliary lines branching from each second gate line GL2 in the second direction DR2. The initialization voltage lines VIL may be located between the auxiliary lines, which branch from each second gate line GL2 in the second direction DR2, and the vertical voltage lines VVSL. The initialization voltage lines VIL may supply an initialization voltage to the pixel circuit of each of the first through third pixels SP1, SP2, and SP3. The initialization voltage lines VIL may receive a sensing signal from the pixel circuit of each of the first through third pixels SP1, SP2, and SP3, and may supply the sensing signal to the display drivers 520.

The vertical voltage lines VVSL may extend in the second direction DR2. The vertical voltage lines VVSL may be respectively located on left sides of the initialization voltage lines VIL. The vertical voltage lines VVSL may be connected between the power supply 550 and a second voltage line VSL. The vertical voltage lines VVSL may supply a low potential voltage received from the power supply 550 to the second voltage line VSL.

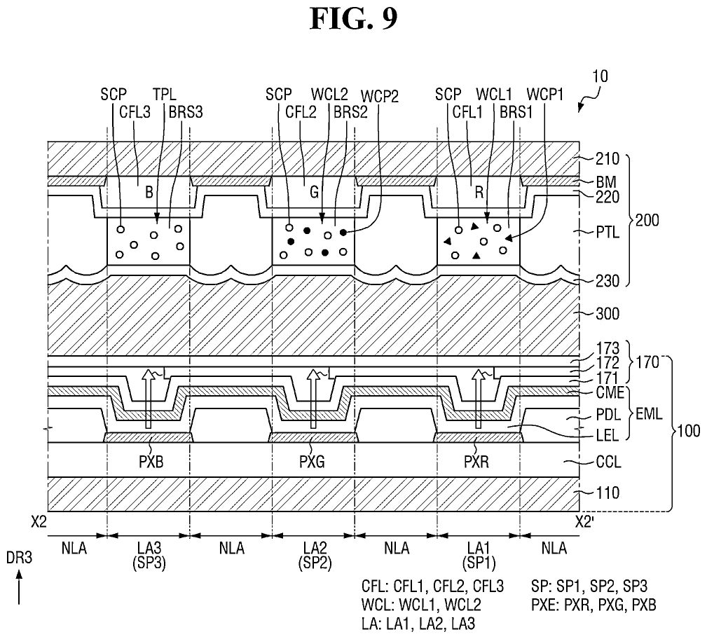

The second voltage line VSL may extend in the first direction DR1. The second voltage line VSL may be located above a first gate line GL1 located in a (k+1)^{th} row ROWₖ₊₁. The second voltage line VSL may supply a low potential voltage received from the vertical voltage lines VVSL to a light-emitting element layer EML (see FIG. 9) of the first through third pixels SP1, SP2, and SP3.

The first gate lines GL1 may extend in the first direction DR1. The first gate lines GL1 may be respectively located above the pixel circuits of the first pixels SP1. At least a portion of each first gate line GL1 may extend in the direction opposite to the second direction DR2. For example, each of the first gate lines GL1 may include vertical auxiliary lines branching on right sides of the first through third pixels SP1, SP2, and SP3, and extending in the direction opposite to the second direction DR2. The auxiliary lines of each of the first gate lines GL1 may be respectively located on the right sides of the pixel circuits of the first through third pixels SP1, SP2, and SP3. Each of the first gate lines GL1 may supply a first gate signal received from the gate drivers 560 to the pixel circuits of the first through third pixels SP1, SP2, and SP3 through the auxiliary lines extending in the direction opposite to the second direction DR2.

The second gate lines GL2 may extend in the first direction DR1. The second gate lines GL2 may be respectively located below the pixel circuits of the third pixels SP3. At least a portion of each second gate line GL2 may extend in the second direction DR2. For example, each of the second gate lines GL2 may include vertical auxiliary lines branching on left sides of the first voltage lines VDL, and extending in the second direction DR2. The auxiliary lines of each of the second gate lines GL2 may be respectively located on the left sides of the first voltage lines VDL. Each of the second gate lines GL2 may supply a second gate signal received from the gate drivers 560 to the pixel circuits of the first through third pixels SP1, SP2, and SP3 through the auxiliary lines extending in the second direction DR2.

The data lines DL may extend in the second direction DR2. The data lines DL may supply data voltages to the pixels SP. The data lines DL may include the first through third data lines DL1, DL2, and DL3.

The second data lines DL2 may extend in the second direction DR2. The second data lines DL2 may be respectively located on right sides of the auxiliary lines of each first gate line GL1. The second data lines DL2 may supply data voltages received from the display drivers 520 to the pixel circuits of the second pixels SP2.

The third data lines DL3 may extend in the second direction DR2. The third data lines DL3 may be respectively located on right sides of the second data lines DL2. The third data lines DL3 may supply data voltages received from the display drivers 520 to the pixel circuits of the third pixels SP3.

The first data lines DL1 may extend in the second direction DR2. The first data lines DL1 may be respectively located on right sides of the third data lines DL3.

The first data lines DL1 may supply data voltages received from the display drivers 520 to the pixel circuits of the first pixels SP1.

In the drawings, the second data lines DL2, the third data lines DL3, and the first data lines DL1 are sequentially arranged in the first direction DR1. However, the present disclosure is not limited thereto. The order in which the first through third data lines DL1, DL2, and DL3 are arranged in the first direction DR1 can be variously changed.

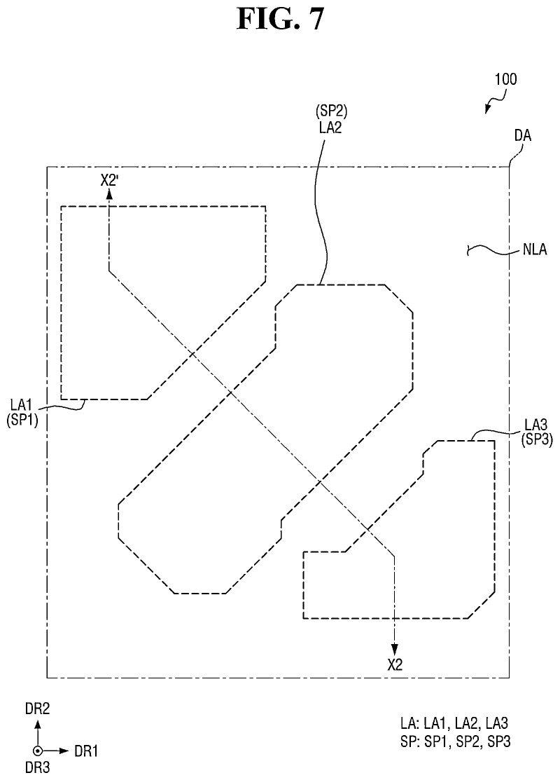

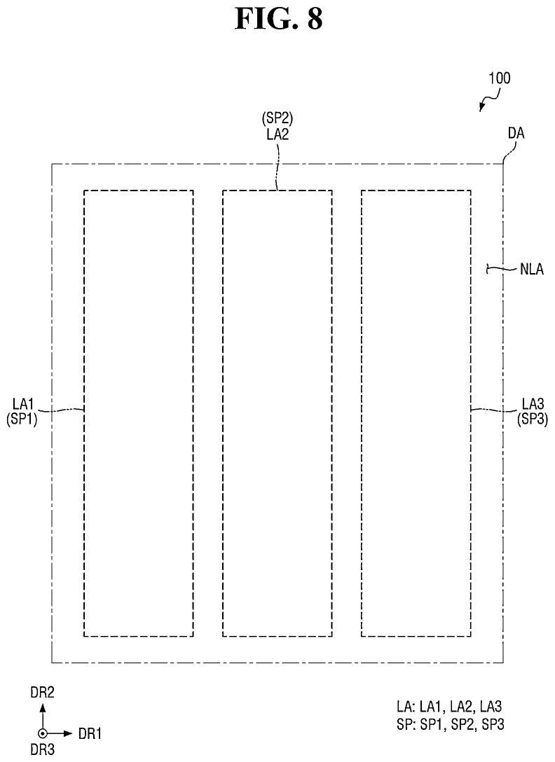

FIG. 7 is a schematic plan view of a part of the display area DA of the display substrate 100 according to one or more embodiments. FIG. 8 is a schematic plan view of a part of a display area DA of a display substrate 100 according to one or more embodiments.

Referring to FIGS. 7 and 8 in addition to FIGS. 1, 2, and 3, a plurality of emission areas LA and a non-emission area NLA may be defined in the display area DA of the display substrate 100. The emission areas LA may be areas where light generated by light-emitting elements of the display substrate 100 is emitted to the outside of the display substrate 100, and the non-emission area NLA may be an area where light generated by the light-emitting elements of the display substrate 100 is not emitted to the outside of the display substrate 100. In some embodiments, the emission areas LA may include a first emission area LA1, a second emission area LA2, and a third emission area LA3.

In some embodiments, the emission areas LA and the non-emission area NLA may be defined by a pixel-defining layer PDL (see FIG. 9). For example, the emission areas LA may be areas overlapping openings of the pixel-defining layer PDL (see FIG. 9), and the non-emission area NLA may be an area not overlapping the openings of the pixel-defining layer PDL (see FIG. 9).

In one or more embodiments, light emitted from the emission areas LA of the display substrate 100 to the color conversion substrate 200 may be light of the third color. For example, the light of the third color may be blue light, and may have a peak wavelength in the range of about 440 to about 480 nm. The peak wavelength may refer to a wavelength having maximum intensity in a wavelength region. However, the present disclosure is not limited thereto, and the light emitted from the emission areas LA of the display substrate 100 to the color conversion substrate 200 may also be light in an ultraviolet region.

If the first through third emission areas LA1, LA2, and LA3 emit light of the same color, the first through third pixels SP1, SP2, and SP3 may express various colors through color conversion patterns included in the color conversion substrate 200.

In one or more embodiments, the first through third emission areas LA1, LA2, and LA3 may emit light of different respective colors. For example, light emitted from the first emission area LA1 may be red light, light emitted from the second emission area LA2 may be green light, and light emitted from the third emission area LA3 may be blue light.

The first emission area LA1, the second emission area LA2, and the third emission area LA3 may constitute a first pixel SP1, a second pixel SP2, and a third pixel SP3, respectively. The first emission area LA1, the second emission area LA2, and the third emission area LA3 may be repeatedly located over the entire display area DA along the first direction DR1 and the second direction DR2. The first emission area LA1, the second emission area LA2, and the third emission area LA3 may constitute one unit color pixel.

In one or more embodiments, referring to FIG. 7, the first through third emission areas LA1, LA2, and LA3 may be arranged in a diagonal direction defined by the directions opposite to the first direction DR1 and the second direction DR2. For example, in one unit color pixel, the first emission area LA1 may be generally located at an upper left corner in plan view, the second emission area LA2 may be generally located at the center in plan view, and the third emission area LA3 may be generally located at a lower right corner in plan view. However, the arrangement order of the first through third emission areas LA1, LA2, and LA3 is not limited thereto.

In one or more embodiments, referring to FIG. 8, the first through third emission areas LA1, LA2, and LA3 may be arranged along the first direction DR1. For example, in one unit color pixel, the first emission area LA1 may be generally located on the left side in plan view, the second emission area LA2 may be generally located at the center in plan view, and the third emission area LA2 may be generally located on the right side in plan view. However, the arrangement order of the first through third emission areas LA1, LA2, and LA3 is not limited thereto.

In one or more embodiments, referring to FIG. 7, the first emission area LA1 may have a polygonal shape extending in the first direction DR1 and the second direction DR2. In the drawing, a pentagon (e.g., irregular pentagon) is illustrated as an example of the shape of the first emission area LA1. The second emission area LA2 may have a polygonal shape generally extending in a diagonal direction defined by the first direction DR1 and the second direction DR2. In the drawing, a polygon having steps at both ends is illustrated as an example of the shape of the second emission area LA2. The third emission area LA3 may have a polygonal shape generally extending in the first direction DR1 and the second direction DR2. In the drawing, a polygon including portions protruding in the direction opposite to the first direction DR1 and in the second direction DR2 is illustrated as an example of the shape of the third emission area LA3.

In one or more embodiments, referring to FIG. 8, the first through third emission areas LA1, LA2, and LA3 may have a polygonal shape extending in the second direction DR2. In the drawing, a quadrilateral is illustrated as an example of the shape of each of the first through third emission areas LA1, LA2, and LA3. However, the shapes of the first through third emission areas LA1, LA2, and LA3 are not limited thereto.

In one or more embodiments, referring to FIG. 7, the widths and shapes of the first through third emission areas LA1, LA2, and LA3 may be different from each other. For example, the first emission area LA1 may have similar widths in the first direction DR1 and the second direction DR2. The second emission area LA2 may have a relatively wide width in the diagonal direction defined by the first direction DR1 and the second direction DR2, and may have a relatively narrow width in the diagonal direction defined by the directions opposite to the first direction DR1 and the second direction DR2. Therefore, the second emission area LA2 may be shaped like a polygon generally extending in the diagonal direction defined by the first direction DR1 and the second direction DR2. The third emission area LA3 may have similar widths in the first direction DR1 and the second direction DR2.

In one or more embodiments, referring to FIG. 8, the widths and shapes of the first through third emission areas LA1, LA2, and LA3 may be the same. For example, the widths of the first through third emission areas LA1, LA2, and LA3 in the first direction DR1 may be the same, and the widths of the first through third emission areas LA1, LA2, and LA3 in the second direction DR2 may be the same.

The non-emission area NLA may be located around the emission areas LA of the display substrate 100 in the display area DA (e.g., in plan view). The non-emission area NLA may be located not only around the emission areas LA, but also between the first emission area LA1 and the second emission area LA2, between the second emission area LA2 and the third emission area LA3, and between the third emission area LA3 and the first emission area LA1.

Light emitted from the emission areas LA of the display substrate 100 may pass through light-transmitting areas of the color conversion substrate 200, and then may be provided to the outside of the display device 10.

FIG. 9 is a cross-sectional view taken along the line X2-X2′ of FIG. 7.

Referring to FIG. 9 in addition to FIGS. 7 and 8, the display device 10 may include the display substrate 100, the color conversion substrate 200 facing the display substrate 100, and the filler 300 bonding the display substrate 100 and the color conversion substrate 200 together.

The display substrate 100 may include a first substrate 110, a circuit layer CCL, a light-emitting element layer EML, and an encapsulation structure 170.

The first substrate 110 may include a transparent material. For example, the first substrate 110 may include a transparent insulating material, such as glass or quartz. The first substrate 110 may be a rigid substrate. However, the first substrate 110 is not limited thereto. The first substrate 110 may also include plastic, such as polyimide, or may have flexible properties so that it can be curved, bent, folded, or rolled.

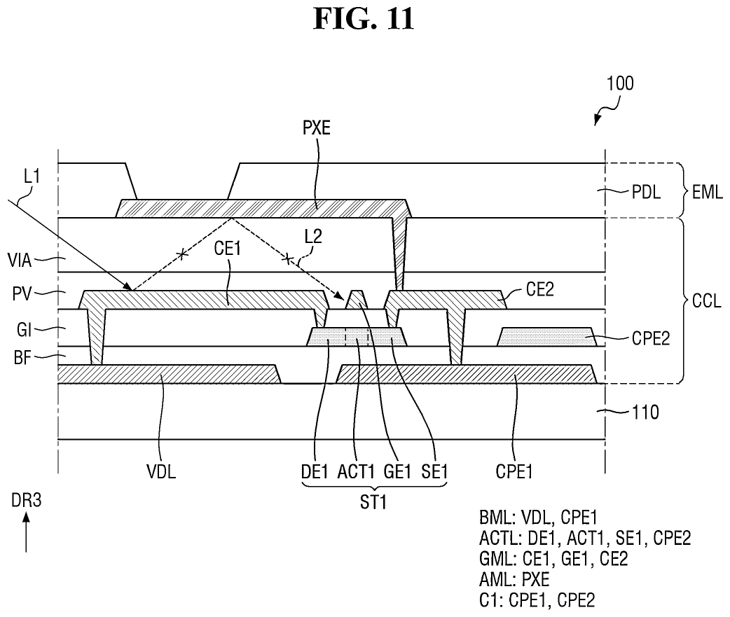

The circuit layer CCL (e.g., thin-film transistor layer) may be located on the first substrate 110. The circuit layer CCL will be described later with reference to FIG. 11, etc.

The light-emitting element layer EML may be located on the circuit layer CCL. The light-emitting element layer EML may include pixel electrodes PXE, the pixel-defining layer PDL, a light-emitting layer LEL, and a common electrode CME.

The pixel electrodes PXE may be first electrodes (e.g., anodes) of light-emitting diodes. The pixel electrodes PXE may have a stacked structure of a material layer having a high work function, such as indium-tin-oxide (ITO), indium-zinc-oxide (IZO), zinc oxide (ZnO), or indium oxide (In₂O₃) and a reflective material layer, such as silver (Ag), magnesium (Mg), aluminum (AI), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be located on the reflective material layer so that it is located close to the light-emitting layer LEL. The pixel electrodes PXE may have, but are not limited to, a multilayer structure of ITO/Mg, ITO/MgF, ITO/Ag, or ITO/Ag/ITO.

The pixel electrodes PXE may include a first pixel electrode PXR, a second pixel electrode PXG, and a third pixel electrode PXB. The first pixel electrode PXR may overlap the first emission area LA1. The second pixel electrode PXG may overlap the second emission area LA2. The third pixel electrode PXB may overlap the third emission area LA3.

The pixel-defining layer PDL may be located on a surface of the first substrate 110 along the boundaries of the pixels SP. The pixel-defining layer PDL may be located on the pixel electrodes PXE, and may include/define openings exposing the pixel electrodes PXE. The emission areas LA and the non-emission area NLA may be defined by the pixel-defining layer PDL and its openings.

The pixel-defining layer PDL may include an organic insulating material, such as polyacrylates resin, epoxy resin, phenolic resin, polyamides resin, polyimides resin, unsaturated polyesters resin, polyphenylenethers resin, polyphenylenesulfides resin, or benzocyclobutene (BCB). The pixel-defining layer PDL may also include an inorganic material.

The light-emitting layer LEL may be located on the pixel electrodes PXE exposed by the pixel-defining layer PDL. The light-emitting layer LEL may contact not only the pixel electrodes PXE, but also side and upper surfaces of the pixel-defining layer PDL. The light-emitting layer LEL may be connected without distinguishing between the emission areas LA and between the pixels SP. The light-emitting layer LEL may be located over the entire surface without distinguishing between the emission areas LA and between the pixels SP. Accordingly, the light-emitting layer LEL of the emission areas LA1, LA2, and LA3 may emit light having the same wavelength. For example, the light-emitting layer LEL of the emission areas LA1, LA2, and LA3 may emit blue light or ultraviolet light, and a wavelength conversion layer WCL included in the color conversion substrate 200 to be described later may enable each pixel SP to display a corresponding color.

In one or more embodiments, light-emitting layers LEL may be respectively located in the emission areas LA1, LA2, and LA3 separated by the pixel-defining layer PDL. In this case, the light-emitting layers LEL of the emission areas LA1, LA2, and LA3 may emit light having the same wavelength.

In one or more embodiments in which the display device 10 is an organic light-emitting display device, the light-emitting layer LEL may include an organic layer including an organic material. The organic layer may include an organic light-emitting layer. In some cases, the organic layer may further include at least one of a hole injection layer, a hole transport layer, an electron transport layer, or an electron injection layer as an auxiliary layer for assisting light emission. In one or more embodiments, if the display device 10 is a micro-LED display device or a nano-LED display device, the light-emitting layer LEL may include an inorganic material, such as an inorganic semiconductor.

In some embodiments, the light-emitting layer LEL may have a tandem structure including a plurality of organic light-emitting layers overlapping each other in a thickness direction and a charge generation layer located between them. The organic light-emitting layers overlapping each other may emit light of the same wavelength or may emit light of different wavelengths. At least some layers of the light-emitting layer LEL of each pixel SP may be separated from those of the light-emitting layer LEL of a neighboring pixel SP by the pixel-defining layer PDL or may be connected to those of the light-emitting layer LEL of the neighboring pixel SP.

The common electrode CME may be located on the light-emitting layer LEL. The common electrode CME may be connected without distinguishing between the emission areas LA and the pixels SP. The common electrode CME may be a whole-surface electrode located over the entire surface without distinguishing between the emission areas LA and between the pixels SP. The common electrode CME may be second electrodes (e.g., cathodes) of the light-emitting diodes. The common electrode CME may include a material layer having a small work function, such as Li, Ca, LiF/Ca, LiF/AI, AI, Mg, Ag, Pt, Pd, Ni, Au Nd, Ir, Cr, BaF, Ba, or a compound or mixture thereof (e.g., a mixture of Ag and Mg). The common electrode CME may further include a transparent metal oxide layer located on the material layer having a small work function.

The pixel electrodes PXE, the light-emitting layer LEL, and the common electrode CME may constitute light-emitting elements (e.g., organic light-emitting diodes). Light emitted from the light-emitting layer LEL may be output upward through the common electrode CME.

The encapsulation structure 170 may be located on the common electrode CME. The encapsulation structure 170 may include at least one thin-film encapsulation layer. For example, the encapsulation structure 170 may include a first encapsulating inorganic layer 171, an encapsulating organic layer 172, and a second encapsulating inorganic layer 173.

The first encapsulating inorganic layer 171 may be located on the light-emitting element layer EML. The first encapsulating inorganic layer 171 may include silicon nitride (SiNₓ), silicon oxide (SiOₓ), or silicon oxynitride (SiOₓN_{y}).

The encapsulating organic layer 172 may be located on the first encapsulating inorganic layer 171. The encapsulating organic layer 172 may include an organic insulating material, such as polyacrylates resin, epoxy resin, phenolic resin, polyamides resin, polyimides resin, unsaturated polyesters resin, polyphenylenethers resin, polyphenylenesulfides resin, or benzocyclobutene (BCB).

The second encapsulating inorganic layer 173 may be located on the encapsulating organic layer 172. The second encapsulating inorganic layer 173 may include the same material as the first encapsulating inorganic layer 171 described above. For example, the second encapsulating inorganic layer 173 may include silicon nitride (SiNₓ), silicon oxide (SiOₓ), or silicon oxynitride (SiOₓN_{y}).

In some embodiments, some layers of the encapsulation structure 170 or the entire encapsulation structure 170 may be omitted. If the encapsulation structure 170 is omitted, the filler 300, the sealing part 400, and the color conversion substrate 200 may be directly located on the light-emitting element layer EML, and may perform an encapsulation function.

The color conversion substrate 200 may be located on the encapsulation structure 170 to face the display substrate 100. The color conversion substrate 200 may include a second substrate 210, a light-blocking member BM, color filter layers CFL, a first capping layer 220, a partition wall PTL, a wavelength conversion layer WCL, a light-transmitting layer TPL, and a second capping layer 230.

The second substrate 210 may include a transparent material. The second substrate 210 may include a transparent insulating material, such as glass or quartz. The second substrate 210 may be a rigid substrate. However, the second substrate 210 is not limited thereto. The second substrate 210 may also include plastic, such as polyimide or may have flexible properties so that it can be curved, bent, folded, or rolled.

The second substrate 210 may be the same substrate as the first substrate 110, but may have a different material, thickness, and transmittance from the first substrate 110. For example, the second substrate 210 may have higher transmittance than the first substrate 110. The second substrate 210 may be thicker or thinner than the first substrate 110.

The light-blocking member BM may be located on a surface of the second substrate 210, which faces the first substrate 110, along the boundaries of the pixels SP. The light-blocking member BM may overlap the pixel-defining layer PDL of the display substrate 100, and may be located in the non-emission area NLA. The light-blocking member BM may include/define openings exposing the surface of the second substrate 210 which overlaps the emission areas LA. The light-blocking member BM may be formed in a lattice shape in plan view.

The light-blocking member BM may include an organic material. The light-blocking member BM may reduce color distortion due to reflection of external light by absorbing the external light. In addition, the light-blocking member BM may reduce or prevent intrusion of light emitted from the light-emitting layer LEL into adjacent pixels SP.

In one or more embodiments, the light-blocking member BM may absorb all visible light wavelengths. The light-blocking member BM may include a light-absorbing material. For example, the light-blocking member BM may be made of a material used as a black matrix of the display device 10.

In one or more embodiments, the light-blocking member BM may absorb light of a corresponding wavelength among the visible light wavelengths, and may transmit light of another corresponding wavelength. For example, the light-blocking member BM may include the same material as a color filter layer CFL. For example, the light-blocking member BM may be made of the same material as a blue color filter layer. In some embodiments, the light-blocking member BM may be integrally formed with the blue color filter layer. The light-blocking member BM may also be omitted.

The color filter layers CFL may be located on the surface of the second substrate 210 on which the light-blocking member BM is located. The color filter layers CFL may be located on the surface of the second substrate 210 exposed through the openings of the light-blocking member BM. Further, each of the color filter layers CFL may be located on a portion of the adjacent light-blocking member BM.

The color filter layers CFL may include a first color filter layer CFL1 located in the first pixel SP1, a second color filter layer CFL2 located in the second pixel SP2, and a third color filter layer CFL3 located in the third pixel SP3. Each color filter layer CFL may include a colorant, such as a dye or pigment that absorbs wavelengths other than a corresponding color wavelength. The first color filter layer CFL1 may be a red color filter layer, the second color filter layer CFL2 may be a green color filter layer, and the third color filter layer CFL3 may be a blue color filter layer. Although neighboring color filter layers CFL are spaced apart from each other on the light-blocking member BM in the drawing, they may also at least partially overlap each other on the light-blocking member BM.

The first capping layer 220 may be located on the color filter layers CFL. The first capping layer 220 may reduce or prevent damage to, or contamination of, the color filter layers CFL by reducing or preventing penetration of impurities, such as moisture or air from the outside into the color filter layers CFL.

The first capping layer 220 may directly contact surfaces (lower surfaces in FIG. 9) of the color filter layers CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, or silicon oxynitride.

The partition wall PTL may be located on the first capping layer 220. The partition wall PTL may be located in the non-emission area NLA. The partition wall PTL may overlap the light-blocking member BM. The partition wall PTL may include/define openings exposing the color filter layers CFL. The partition wall PTL may include, but is not limited to, a photosensitive organic material. The partition wall PTL may further include a light-blocking material.

The wavelength conversion layer WCL and/or the light-transmitting layer TPL may be located in spaces exposed by the openings of the partition wall PTL. The wavelength conversion layer WCL and the light-transmitting layer TPL may be formed by an inkjet process using the partition wall PTL as a bank, but the present disclosure is not limited thereto.

In one or more embodiments in which the light-emitting layer LEL of each pixel SP emits light of the third color, the wavelength conversion layer WCL may include a first wavelength conversion pattern WCL1 located in the first pixel SP1 and a second wavelength conversion pattern WCL2 located in the second pixel SP2. The light-transmitting layer TPL may be located in the third pixel SP3.

The first wavelength conversion pattern WCL1 may include a first base resin BRS1, and first wavelength conversion materials WCP1 located in the first base resin BRS1. The second wavelength conversion pattern WCL2 may include a second base resin BRS2, and second wavelength conversion materials WCP2 located in the second base resin BRS2. The light-transmitting layer TPL may include a third base resin BRS3, and scatterers SCP located in the third base resin BRS3.

The first through third base resins BRS1, BRS2, and BRS3 may include a light-transmitting organic material. For example, the first through third base resins BRS1, BRS2, and BRS3 may include epoxy resin, acrylic resin, cardo resin, or imide resin. The first through third base resins BRS1, BRS2, and BRS3 may all be made of the same material, but the present disclosure is not limited thereto.

The scatterers SCP may be metal oxide particles or organic particles. The metal oxide may be, for example, titanium oxide (TiO₂), zirconium oxide (ZrO₂), aluminum oxide (Al₂O₃), indium oxide (In₂O₃), zinc oxide (ZnO), or tin oxide (SnO₂), and the organic particle material may be, for example, acrylic resin or urethane resin.

The first wavelength conversion materials WCP1 may convert the third color into the first color, and the second wavelength conversion materials WCP2 may convert the third color into the second color. The first wavelength conversion materials WCP1 and the second wavelength conversion materials WCP2 may be quantum dots, quantum rods, or phosphors. The quantum dots may include Group IV nanocrystals, Group II-VI compound nanocrystals, Group III-V compound nanocrystals, Group IV-VI nanocrystals, or a combination thereof. The first wavelength conversion pattern WCL1 and the second wavelength conversion pattern WCL2 may further include scatterers SCP to increase wavelength conversion efficiency.

The light-transmitting layer TPL located in the third pixel SP3 may transmit light of the third color emitted from the light-emitting layer LEL while maintaining the wavelength of the light. The scatterers SCP of the light-transmitting layer TPL may control an emission path of light emitted through the light-transmitting layer TPL. The light-transmitting layer TPL may not include a wavelength conversion material.

The second capping layer 230 may be located on the wavelength conversion layer WCL, the light-transmitting layer TPL, and the partition wall PTL. The second capping layer 230 may be made of an inorganic material. The second capping layer 230 may include a material selected from the materials listed as materials of the first capping layer 220. The second capping layer 230 and the first capping layer 220 may be made of the same material, but the present disclosure is not limited thereto.

The filler 300 may be located between the display substrate 100 and the color conversion substrate 200. The filler 300 may fill the space between the display substrate 100 and the color conversion substrate 200, and may bond and couple them to each other. The filler 300 may be located between the encapsulation structure 170 of the display substrate 100 and the second capping layer 230 of the color conversion substrate 200. The filler 300 may be made of, but not limited to, a Si-based organic material or an epoxy-based organic material.

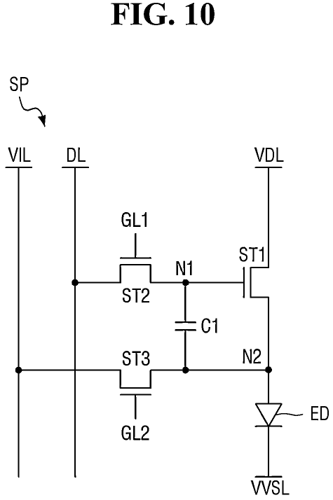

FIG. 10 is an equivalent circuit diagram of a pixel SP according to one or more embodiments.

Referring to FIG. 10, each pixel SP may be connected to a first voltage line VDL, a data line DL, an initialization voltage line VIL, a first gate line GL1, a second gate line GL2, and a vertical voltage line VVSL.

Each pixel SP may include a pixel circuit and a light-emitting element ED. In one or more embodiments, as illustrated in the drawing, the pixel circuit of each pixel SP may have a 3T1C structure including three transistors and one capacitor. For example, the pixel circuit of each pixel SP may include first through third transistors ST1, ST2, and ST3 and a capacitor C1. However, the present disclosure is not limited thereto, and the number of transistors and capacitors in each pixel circuit can be variously changed. Although the 3T1C structure is described below as an example for ease of description, the present disclosure is not limited thereto, and other various modified structures, such as a 2T1C structure, a 7T1C structure, a 6T1C structure, and a 7T3C structure are also applicable.

The first transistor ST1 may include a gate electrode, a drain electrode, and a source electrode. The first transistor ST1 may have the gate electrode connected to a first node N1, the drain electrode connected to the first voltage line VDL, and the source electrode connected to a second node N2. The first transistor ST1 may control a drain-source current (or a driving current) based on a data voltage applied to the gate electrode. The first transistor ST1 may be a driving transistor that drives the light-emitting element ED.

The light-emitting element ED may emit light in response to a driving current received. The amount of light emitted from the light-emitting element ED or the luminance of the light-emitting element ED may be proportional to the magnitude of the driving current. The light-emitting element ED may be an organic light-emitting diode including an organic light-emitting layer, a quantum dot light-emitting diode including a quantum dot light-emitting layer, a micro light-emitting diode, or an inorganic light-emitting diode including an inorganic semiconductor.

A first electrode (e.g., pixel electrode) of the light-emitting element ED may be connected to the second node N2, and a second electrode of the light-emitting element ED may be connected to the vertical voltage line VVSL. The first electrode of the light-emitting element ED may be connected to the source electrode of the first transistor ST1, a drain electrode of the third transistor ST3, and a first capacitor electrode of the capacitor C1 through the second node N2.

The second transistor ST2 may be turned on by a first gate signal of the first gate line GL1 to electrically connect the data line DL and the first node N1 which is the gate electrode of the first transistor ST1. The second transistor ST2 may be turned on based on the first gate signal to supply a data voltage to the first node N1. The second transistor ST2 may have a gate electrode connected to the first gate line GL1, a drain electrode connected to the data line DL, and a source electrode connected to the first node N1. The source electrode of the second transistor ST2 may be connected to the gate electrode of the first transistor ST1 and a second capacitor electrode of the capacitor C1 through the first node N1. The second transistor ST2 may be a switching transistor that controls a current flowing through the first transistor ST1 and the light-emitting element ED.

The third transistor ST3 may be turned on by a second gate signal of the second gate line GL2 to electrically connect the initialization voltage line VIL and the second node N2 which is the source electrode of the first transistor ST1. The third transistor ST3 may be turned on based on the second gate signal to supply an initialization voltage to the second node N2. The third transistor ST3 may be turned on based on the second gate signal to supply a sensing signal to the initialization voltage line VIL. The third transistor ST3 may have a gate electrode connected to the second gate line GL2, the drain electrode connected to the second node N2, and a source electrode connected to the initialization voltage line VIL. The drain electrode of the third transistor ST3 may be connected to the source electrode of the first transistor ST1, the first capacitor electrode of the capacitor C1, and the first electrode of the light-emitting element ED through the second node N2. The third transistor ST3 may be a switching transistor that controls a current flowing through the first transistor ST1 and the light-emitting element ED.

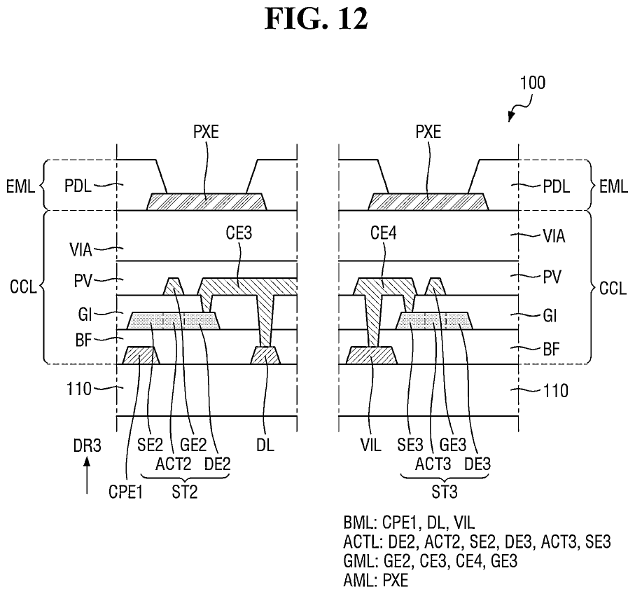

FIG. 11 is a cross-sectional view of an example of a first transistor ST1 of a circuit layer CCL according to one or more embodiments. FIG. 12 is a cross-sectional view of an example of a second transistor ST2 and a third transistor ST3 of the circuit layer CCL according to one or more embodiments.

Referring to FIGS. 11 and 12 in addition to FIG. 10, the display substrate 100 may include the first substrate 110, the circuit layer CCL, and the light-emitting element layer EML.

Because the first substrate 110 has been described above with reference to FIG. 9, a description thereof will be omitted.

The circuit layer CCL may be located on (e.g., above) the first substrate 110. The circuit layer CCL (e.g., thin-film transistor layer) may include a bottom conductive layer BML, a buffer layer BF, an active layer ACTL, a gate-insulating layer GI, a gate conductive layer GML, a passivation layer PV, and a via layer VIA. The circuit layer CCL may include the first through third transistors ST1, ST2, and ST3 and a capacitor C1.

The bottom conductive layer BML may be located on the first substrate 110. The bottom conductive layer BML may include a single layer or a multilayer made of any one or more of molybdenum (Mo), aluminum (AI), chromium (Cr), gold (Au), titanium (Ti), nickel (Ni), neodymium (Nd), copper (Cu), or alloys thereof.

In one or more embodiments, the bottom conductive layer BML may include an initialization voltage line VIL, a data line DL, a first voltage line VDL, a vertical voltage line VVSL, and a first capacitor electrode CPE1 of the capacitor C1.

The buffer layer BF may be located on the bottom conductive layer BML. The buffer layer BF may include an inorganic material, such as a silicon nitride layer, a silicon oxynitride layer, a silicon oxide layer, a titanium oxide layer, or an aluminum oxide layer. Alternatively, the buffer layer BF may include a multilayer in which a plurality of layers selected from a silicon nitride layer, a silicon oxynitride layer, a silicon oxide layer, a titanium oxide layer, and an aluminum oxide layer are alternately stacked.

The active layer ACTL may be located on the buffer layer BF. The active layer ACTL may include polycrystalline silicon, monocrystalline silicon, low-temperature polycrystalline silicon, amorphous silicon, or an oxide semiconductor material.

In one or more embodiments, the active layer ACTL may include a first active region ACT1, a first drain electrode DE1, and a first source electrode SE1 of the first transistor ST1, a second active region ACT2, a second drain electrode DE2, and a second source electrode SE2 of the second transistor ST2, a third active region ACT3, a third drain electrode DE3, and a third source electrode SE3 of the third transistor ST3, and a second capacitor electrode CPE2 of the capacitor C1.

The gate-insulating layer GI may be located on the active layer ACTL. The gate-insulating layer GI may include an inorganic layer, such as a silicon nitride layer, a silicon oxynitride layer, a silicon oxide layer, a titanium oxide layer, or an aluminum oxide layer.

The gate conductive layer GML may be located on the gate-insulating layer GI. The gate conductive layer GML may include a single layer or a multilayer made of any one or more of molybdenum (Mo), aluminum (AI), chromium (Cr), gold (Au), titanium (Ti), nickel (Ni), neodymium (Nd), copper (Cu), or alloys thereof.

In one or more embodiments, the gate conductive layer GML may include a first gate line GL1, a second gate line GL2, a first gate electrode GE1 of the first transistor ST1, a second gate electrode GE2 of the second transistor ST2, a third gate electrode GE3 of the third transistor ST3, and connection electrodes CE1, CE2, CE3, and CE4.

In the display device 10, the gate conductive layer GML may have lower reflectivity than at least one of the bottom conductive layer BML or an anode conductive layer AML. The gate conductive layer GML may further include a material for lowering reflectivity. For example, the gate conductive layer GML may include aluminum-zinc-tin-oxide (AZTO).

First light L1, such as light coming from the outside or light emitted from an adjacent pixel, may be reflected from an upper surface of the gate conductive layer GML. Second light L2 reflected from the upper surface of the gate conductive layer GML may be reflected again from a lower surface of the anode conductive layer AML to enter the active layer ACTL. Accordingly, light-induced degradation may occur. The light-induced degradation refers to a phenomenon in which a characteristic curve between a drain-source current Ids and a gate voltage Vg of a transistor is shifted due to external light incident on the transistor, thus changing the magnitude of a threshold voltage Vth.

In the display device 10, the gate conductive layer GML further including a material for lowering reflectivity can reduce reflected light, such as the second light L2. Accordingly, the light-induced degradation can be reduced or minimized, thereby improving the reliability of the display device 10.

The passivation layer PV may be located on the gate conductive layer GML. The passivation layer PV may include an inorganic layer, such as a silicon nitride layer, a silicon oxynitride layer, a silicon oxide layer, a titanium oxide layer, or an aluminum oxide layer.

The via layer VIA may be located on the passivation layer PV. The via layer VIA may include an organic layer, such as acryl resin, epoxy resin, phenolic resin, polyamide resin, or polyimide resin.

The circuit layer CCL may include the first through third transistors ST1, ST2, and ST3 and the capacitor C1.

The first transistor ST1 may include the first active region ACT1, the first gate electrode GE1, the first drain electrode DE1, and the first source electrode SE1.

The first active region ACT1 may be located in the active layer ACTL. The first active region ACT1 may be overlapped by the first gate electrode GE1 in the third direction DR3. The first active region ACT1 may be a region where the active layer ACTL is not made conductive in an area overlapped by the first gate electrode GE1.

The first gate electrode GE1 may be located in the gate conductive layer GML. Referring to FIG. 10, the first gate electrode GE1 may be connected to the second source electrode SE2 of the second transistor ST2 and the second capacitor electrode CPE2 of the capacitor C1 through a first node N1.

In the drawings, the first transistor ST1 is illustrated as having a top gate structure in which the first gate electrode GE1 is located above the first active region ACT1. However, the present disclosure is not limited thereto. For example, the first transistor ST1 may also have a bottom gate structure in which the first gate electrode GE1 is located below the first active region ACT1. For another example, the first transistor ST1 may have a double gate structure in which the first gate electrode GE1 is located both above and below the first active region ACT1.

The first drain electrode DE1 and the first source electrode SE1 may be formed by heat-treating the active layer ACTL to make it conductive. The first drain electrode DE1 and the first source electrode SE1 may be, but are not limited to, P-type semiconductors or N-type semiconductors.

Referring to FIG. 10, the first drain electrode DE1 may be electrically connected to the first voltage line VDL. For example, referring to FIG. 11, the first drain electrode DE1 may be connected to the first voltage line VDL through a first connection electrode CE1. Accordingly, the first drain electrode DE1 may receive a driving voltage from the first voltage line VDL.

Referring to FIG. 10, the first source electrode SE1 may be connected to a light-emitting element ED through a second node N2. For example, referring to FIG. 11, the first source electrode SE1 may be connected to a pixel electrode PXE through a second connection electrode CE2. Accordingly, the first source electrode SE1 may supply a driving current to the light-emitting element ED.

Referring to FIG. 10, the first source electrode SE1 may be connected to the capacitor C1 through the second node N2. For example, referring to FIG. 11, the first source electrode SE1 may be connected to the first capacitor electrode CPE1 of the capacitor C1 through the second connection electrode CE2.

The second transistor ST2 may include the second active region ACT2, the second gate electrode GE2, the second drain electrode DE2, and the second source electrode SE2.

The second active region ACT2 may be located in the active layer ACTL.

The second active region ACT2 may be overlapped by the second gate electrode GE2 in the third direction DR3. The second active region ACT2 may be a region where the active layer ACTL is not made conductive in an area overlapped by the second gate electrode GE2.

The second gate electrode GE2 may be located in the gate conductive layer GML. Referring to FIG. 10, the second gate electrode GE2 may be connected to the first gate line GL1. Accordingly, the second gate electrode GE2 may receive a first gate signal from the first gate line GL1.

In the drawings, the second transistor ST2 is illustrated as having a top gate structure in which the second gate electrode GE2 is located above the second active region ACT2. However, the present disclosure is not limited thereto. For example, the second transistor ST2 may also have a bottom gate structure in which the second gate electrode GE2 is located below the second active region ACT2. For another example, the second transistor ST2 may have a double gate structure in which the second gate electrode GE2 is located both above and below the second active region ACT2.

The second drain electrode DE2 and the second source electrode SE2 may be formed by heat-treating the active layer ACTL to make it conductive. The second drain electrode DE2 and the second source electrode SE2 may be, but are not limited to, P-type semiconductors or N-type semiconductors.

Referring to FIG. 10, the second drain electrode DE2 may be electrically connected to the data line DL. For example, referring to FIG. 12, the second drain electrode DE2 may be connected to the data line DL through a third connection electrode CE3. Accordingly, the second drain electrode DE2 may receive a data voltage from the data line DL.

Referring to FIG. 10, the second source electrode SE2 may be connected to the first gate electrode GE1 of the first transistor ST1 through the first node N1. Accordingly, the second source electrode SE2 may supply a data voltage to the first gate electrode GE1 of the first transistor ST1 through the first node N1. The first transistor ST1 may control a driving current based on the data voltage received from the second source electrode SE2.

Referring to FIG. 10, the second source electrode SE2 may be connected to the capacitor C1 through the first node N1. For example, in one or more embodiments, the second source electrode SE2 may be connected to the second capacitor electrode CPE2 of the capacitor C1 through a separate connection electrode located in the gate conductive layer GML.

The third transistor ST3 may include the third active region ACT3, the third gate electrode GE3, the third drain electrode DE3, and the third source electrode SE3.

The third active region ACT3 may be located in the active layer ACTL. The third active region ACT3 may be overlapped by the third gate electrode GE3 in the third direction DR3. The third active region ACT3 may be a region where the active layer ACTL is not made conductive in an area overlapped by the third gate electrode GE3.

The third gate electrode GE3 may be located in the gate conductive layer GML. Referring to FIG. 10, the third gate electrode GE3 may be connected to the second gate line GL2. Accordingly, the third gate electrode GE3 may receive a second gate signal from the second gate line GL2.

In the drawings, the third transistor ST3 is illustrated as having a top gate structure in which the third gate electrode GE3 is located above the third active region ACT3. However, the present disclosure is not limited thereto. For example, the third transistor ST3 may also have a bottom gate structure in which the third gate electrode GE3 is located below the third active region ACT3. For another example, the third transistor ST3 may have a double gate structure in which the third gate electrode GE3 is located both above and below the third active region ACT3.

The third drain electrode DE3 and the third source electrode SE3 may be formed by heat-treating the active layer ACTL to make it conductive. The third drain electrode DE3 and the third source electrode SE3 may be, but are not limited to, P-type semiconductors or N-type semiconductors.

Referring to FIG. 10, the third drain electrode DE3 may be electrically connected to the first source electrode SE1 of the first transistor ST1. For example, in one or more embodiments, the third drain electrode DE3 may be connected to the first source electrode SE1 of the first transistor ST1 through a separate connection electrode located in the gate conductive layer GML.

Referring to FIG. 10, the third drain electrode DE3 may be connected to the capacitor C1. For example, in one or more embodiments, the third drain electrode DE3 may be connected to the first capacitor electrode CPE1 of the capacitor C1 through a separate connection electrode located in the gate conductive layer GML.

Referring to FIG. 10, the third source electrode SE3 may be connected to the initialization voltage line VIL. For example, referring to FIG. 12, the third source electrode SE3 may be connected to the initialization voltage line VIL through a fourth connection electrode CE4. Accordingly, the third source electrode SE3 may receive an initialization voltage from the initialization voltage line VIL, and may supply a sensing signal to the initialization voltage line VIL.

The capacitor C1 may include the first capacitor electrode CPE1 and the second capacitor electrode CPE2.

The first capacitor electrode CPE1 may be located in the bottom conductive layer BML. The first capacitor electrode CPE1 may be connected to the first source electrode SE1 of the first transistor ST1 through the second connection electrode CE2. The first capacitor electrode CPE1 may be connected to the third drain electrode DE3 of the third transistor ST3 through a separate connection electrode located in the gate conductive layer GML.

The second capacitor electrode CPE2 may be located in the active layer ACTL. The second capacitor electrode CPE2 may be connected to the first gate electrode GE1 of the first transistor ST1 through a separate connection electrode located in the gate conductive layer GML. The second capacitor electrode CPE2 may be connected to the second source electrode SE2 of the second transistor ST2 through a separate connection electrode located in the gate conductive layer GML.

The light-emitting element layer EML may include the anode conductive layer AML and the pixel-defining layer PDL.

Because the pixel-defining layer PDL has been described above with reference to FIG. 9, a description thereof will be omitted.

The anode conductive layer AML may be located on the circuit layer CCL. For example, the anode conductive layer AML may be located on the via layer VIA. In one or more embodiments, the anode conductive layer AML may include the pixel electrode PXE.

The anode conductive layer AML may have a stacked structure of a material layer having a high work function, such as indium-tin-oxide (ITO), indium-zinc-oxide (IZO), zinc oxide (ZnO), or indium oxide (In₂O₃) and a reflective material layer, such as silver (Ag), magnesium (Mg), aluminum (AI), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be located on the reflective material layer so that it is located close to the light-emitting layer LEL. The pixel electrode PXE may have, but is not limited to, a multilayer structure of ITO/Mg, ITO/MgF, ITO/Ag, or ITO/Ag/ITO.

In the display device 10, the number of layers included in the circuit layer CCL is reduced or minimized to reduce the number of masks suitable to pattern each layer. Accordingly, process efficiency can be improved.

For example, lines, such as the data lines DL, the initialization voltage lines VIL, the first voltage lines VDL, and the vertical voltage lines VVSL are placed in the bottom conductive layer BML, and lines, such as the gate lines GL, the horizontal voltage lines HVDL, and the second voltage lines VSL are placed in the gate conductive layer GML. Therefore, because a layer for placing the lines is not added, the number of layers can be reduced or minimized.

For another example, the first capacitor electrode CPE1 is placed in the bottom conductive layer BML, and the second capacitor electrode CPE2 is placed in the active layer ACTL. Therefore, because a layer for placing the capacitor C1 is not added, the number of layers can be reduced or minimized.

For another example, connection electrodes for connecting the bottom conductive layer BML, the active layer ACTL, and the gate conductive layer GML are placed in the gate conductive layer GML. Therefore, because a layer for placing the connection electrodes is not added, the number of layers can be reduced or minimized.

In the display device 10, because the number of layers included in the circuit layer CCL is reduced or minimized, a distance between the light-emitting element layer EML and the active layer ACTL in the third direction DR3 may be reduced. Accordingly, light coming from the outside or light emitted from an adjacent pixel may suitably enter the active layer ACTL. To reduce or minimize the resultant light-induced degradation, the gate conductive layer GML of the display device 10 may include a reflectivity reduction structure.

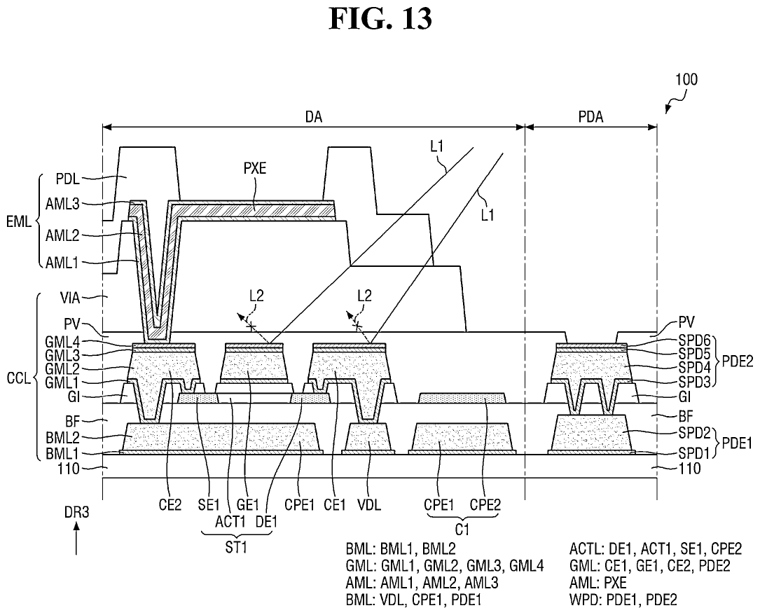

The reflectivity reduction structure of the gate conductive layer GML will now be described with reference to FIG. 13, etc.

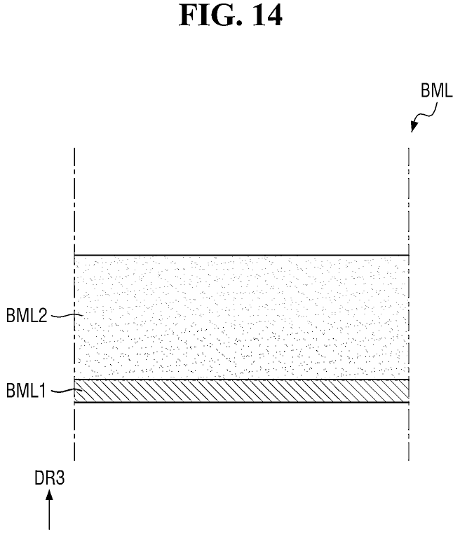

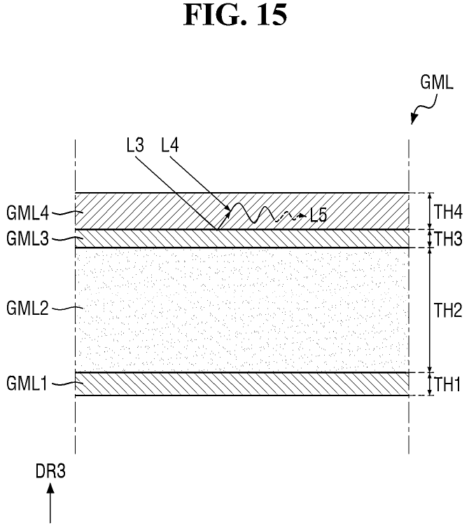

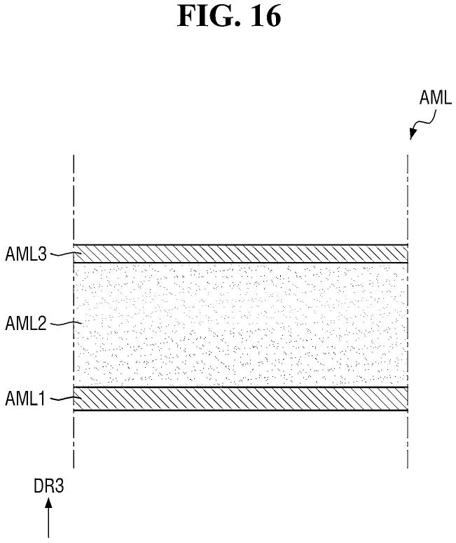

FIG. 13 is a cross-sectional view illustrating an example of a part of the display area DA and a part of the pad area PDA of the display device 10 according to one or more embodiments. FIG. 14 is a cross-sectional view of an example of a bottom conductive layer BML according to one or more embodiments. FIG. 15 is a cross-sectional view of an example of a gate conductive layer GML according to one or more embodiments. FIG. 16 is a cross-sectional view of an example of an anode conductive layer AML according to one or more embodiments.

FIG. 13 illustrates example cross-sections of a first transistor ST1 and a capacitor C1 in the display area DA, and illustrates an example cross-section of a wiring pad WPD in the pad area PDA.

Referring to FIGS. 13 through 16, the display device 10 may include the display area DA and the pad area PDA. The display area DA is an area that displays an image, and may be generally a central area of the display substrate 100. The pad area PDA may be an area where the wiring pad WPD is located. Because the display area DA and the pad area PDA have been described above with reference to FIG. 5, a description thereof will be omitted.

Referring to FIGS. 13 and 14, the bottom conductive layer BML may include a first bottom conductive layer BML1 and a second bottom conductive layer BML2.

The first bottom conductive layer BML1 may be located on (as used herein, “on” may mean “above”) the first substrate 110. The first bottom conductive layer BML1 may be a layer for improving adhesion between the first substrate 110 and the bottom conductive layer BML. For example, the first bottom conductive layer BML1 may include molybdenum (Mo), aluminum (AI), chromium (Cr), gold (Au), titanium (Ti), nickel (Ni), neodymium (Nd), copper (Cu), or an alloy thereof. For example, the first bottom conductive layer BML1 may include, but is not limited to, titanium (Ti).

The second bottom conductive layer BML2 may be located on the first bottom conductive layer BML1. The second bottom conductive layer BML2 may include a material with excellent electrical conductivity. For example, the third bottom conductive layer BML3 may include molybdenum (Mo), aluminum (AI), chromium (Cr), gold (Au), titanium (Ti), nickel (Ni), neodymium (Nd), copper (Cu), or an alloy thereof. For example, the second bottom conductive layer BML2 may include, but is not limited to, copper (Cu).

Referring to FIGS. 13 and 15, the gate conductive layer GML may include a first gate conductive layer GML1, a second gate conductive layer GML2, a third gate conductive layer GML3, and a fourth gate conductive layer GML4.

The first gate conductive layer GML1 may be located on the gate-insulating layer GI. The first gate conductive layer GML1 may be a layer for improving adhesion between the gate-insulating layer GI and the gate conductive layer GML. For example, the first gate conductive layer GML1 may include molybdenum (Mo), aluminum (AI), chromium (Cr), gold (Au), titanium (Ti), nickel (Ni), neodymium (Nd), copper (Cu), or an alloy thereof. For example, the first gate conductive layer GML1 may include, but is not limited to, titanium (Ti). In one or more embodiments, a thickness TH1 of the first gate conductive layer GML1 may be, but is not limited to, about 200 Å to about 300 Å.

The second gate conductive layer GML2 may be located on the first gate conductive layer GML1. The second gate conductive layer GML2 may include a material with excellent electrical conductivity. For example, the second gate conductive layer GML2 may include molybdenum (Mo), aluminum (AI), chromium (Cr), gold (Au), titanium (Ti), nickel (Ni), neodymium (Nd), copper (Cu), or an alloy thereof. For example, the second gate conductive layer GML2 may include, but is not limited to, copper (Cu). In one or more embodiments, a thickness TH2 of the second gate conductive layer GML2 may be, but is not limited to, about 5000 Å to about 10000 Å.

The third gate conductive layer GML3 may be located on the second gate conductive layer GML2. The third gate conductive layer GML3 may include a material with a high extinction coefficient and low reflectivity. For example, the third gate conductive layer GML3 may include molybdenum (Mo), aluminum (AI), chromium (Cr), gold (Au), titanium (Ti), nickel (Ni), neodymium (Nd), copper (Cu), or an alloy thereof. For example, the third gate conductive layer GML3 may include, but is not limited to, titanium (Ti). In one or more embodiments, a thickness TH3 of the third gate conductive layer GML3 may be, but is not limited to, about 100 Å to about 200 Å.

The fourth gate conductive layer GML4 may be located on the third gate conductive layer GML3. The fourth gate conductive layer GML4 may include a material with high light transmittance. The fourth gate conductive layer GML4 may include transparent conductive oxide (TCO). For example, the fourth gate conductive layer GML4 may include aluminum-zinc-tin-oxide (AZTO).

In some embodiments, the fourth gate conductive layer GML4 may include about 1 at % to about 10 at % of aluminum based on atoms excluding oxygen atoms. The fourth gate conductive layer GML4 may include about 60 at % to about 90 at % of zinc based on the atoms excluding the oxygen atoms. The fourth gate conductive layer GML4 may include about 10 at % to about 30 at % of tin based on the atoms excluding the oxygen atoms. Here, the respective ratios of aluminum, zinc, and tin included in the fourth gate conductive layer GML4 refer to the ratios of the numbers of individual particles of aluminum, zinc, and tin atoms to the total number of particles of the aluminum, zinc, and tin atoms which are the atoms excluding the oxygen atoms.

In some embodiments, the fourth gate conductive layer GML4 may include about 0.5 at % to about 5 at % of aluminum based on total atoms including oxygen atoms. The fourth gate conductive layer GML4 may include about 20 at % to about 40 at % of zinc based on the total atoms including the oxygen atoms. The fourth gate conductive layer GML4 may include about 7 at % to about 15 at % of tin based on the total atoms including the oxygen atoms. The fourth gate conductive layer GML4 may include about 50 at % to about 60 at % of oxygen based on the total atoms including the oxygen atoms. Here, the respective ratios of aluminum, zinc, tin, and oxygen included in the fourth gate conductive layer GML4 refer to the ratios of the numbers of individual particles of aluminum, zinc, tin, and oxygen atoms to the total number of particles of the aluminum, zinc, tin, and oxygen atoms.

In some embodiments, the reflectivity of the third gate conductive layer GML3 may be lower than the reflectivity of the fourth gate conductive layer GML4. The light transmittance of the fourth gate conductive layer GML4 may be higher than the light transmittance of the third gate conductive layer GML3.

In the display device 10, the reflectivity of the gate conductive layer GML can be reduced by adjusting the thickness TH3 of the third gate conductive layer GML3 and a thickness TH4 of the fourth gate conductive layer GML4.

For example, referring to FIG. 15, third light L3 incident on the gate conductive layer GML may pass through the fourth gate conductive layer GML4, and may be partially absorbed by the third gate conductive layer GML3. A portion of the third light L3, which is not absorbed by the third gate conductive layer GML3, may be reflected by the third gate conductive layer GML3 to destructively interfere with fourth light L4 incident later. The result may be fifth light L5 whose energy decreases or disappears. Accordingly, the reflectivity of the gate conductive layer GML may be reduced.

In some embodiments, the thickness TH4 of the fourth gate conductive layer GML4 may be greater than the thickness TH3 of the third gate conductive layer GML3. For example, the thickness TH4 of the fourth gate conductive layer GML4 may be about 2 times to about 30 times the thickness TH3 of the third gate conductive layer GML3.

In some embodiments, the thickness TH4 of the fourth gate conductive layer GML4 may be about 400 Å to about 3000 Å. If the thickness TH4 of the fourth gate conductive layer GML4 is less than about 400 Å, a reflectivity reduction may not occur. If the thickness TH4 of the fourth gate conductive layer GML4 exceeds about 3000 Å, process efficiency may decrease, and the reliability of the conductive layer may decrease due to the heat applied during the process of forming the conductive layer. For example, the thickness TH4 of the fourth gate conductive layer GML4 may be about 400 Å to about 1500 Å.

Referring to FIGS. 13 and 16, the anode conductive layer AML may include a first anode conductive layer AML1, a second anode conductive layer AML2, and a third anode conductive layer AML3.

The first anode conductive layer AML1 may be located on the via layer VIA. The second anode conductive layer AML2 may be located on the first anode conductive layer AML1. The third anode conductive layer AML3 may be located on the second anode conductive layer AML2.

The first anode conductive layer AML1 and the third anode conductive layer AML3 may include a material with a high work function and high light transmittance. For example, the first anode conductive layer AML1 and the third anode conductive layer AML3 may include at least any one of indium-tin-oxide (ITO), indium-zinc-oxide (IZO), zinc oxide (ZnO), or indium oxide (In₂O₃). For example, the first anode conductive layer AML1 and the third anode conductive layer AML3 may include, but are not limited to, indium-tin-oxide (ITO).

The second anode conductive layer AML2 may include a material with high reflectivity. For example, the second anode conductive layer AML2 may include silver (Ag), magnesium (Mg), aluminum (AI), platinum (Pt), lead (Pd), gold (Au), nickel (Ni), neodymium (Nd), iridium (Ir), chromium (Cr), lithium (Li), calcium (Ca), or a mixture thereof. For example, the second anode conductive layer AML2 may include, but is not limited to, silver (Ag).

In the display device 10, because the third gate conductive layer GML3 includes a material with low reflectivity, and because the fourth gate conductive layer GML4 includes a material with high light transmittance, the gate conductive layer GML may have lower reflectivity than the bottom conductive layer BML and the anode conductive layer AML. Accordingly, reflection of light incident from the outside, or light incident from an adjacent pixel, from the gate conductive layer GML and the anode conductive layer AML into the active layer ACTL can be reduced or prevented. Therefore, the light-induced degradation can be reduced or minimized.

The display device 10 may include the wiring pad WPD located in the pad area PDA. In some embodiments, the wiring pad WPD may include a first pad electrode PDE1 and a second pad electrode PDE2.

The first pad electrode PDE1 may be located in the bottom conductive layer BML. The first pad electrode PDE1 may include the same material as the bottom conductive layer BML of the display area DA. For example, the first pad electrode PDE1 may include a single layer or a multilayer made of any one or more of molybdenum (Mo), aluminum (AI), chromium (Cr), gold (Au), titanium (Ti), nickel (Ni), neodymium (Nd), copper (Cu), or alloys thereof.

In some embodiments, the first pad electrode PDE1 may include a first sub-pad SPD1 and a second sub-pad SPD2.

The first sub-pad SPD1 may be located in the first bottom conductive layer BML1. The first sub-pad SPD1 may include the same material as the first bottom conductive layer BML1 of the display area DA. For example, the first sub-pad SPD1 may include molybdenum (Mo), aluminum (AI), chromium (Cr), gold (Au), titanium (Ti), nickel (Ni), neodymium (Nd), copper (Cu), or an alloy thereof. For example, the first sub-pad SPD1 may include, but is not limited to, titanium (Ti).

The second sub-pad SPD2 may be located in the second bottom conductive layer BML2. The second sub-pad SPD2 may include the same material as the second bottom conductive layer BML2 of the display area DA. For example, the second sub-pad SPD2 may include molybdenum (Mo), aluminum (AI), chromium (Cr), gold (Au), titanium (Ti), nickel (Ni), neodymium (Nd), copper (Cu), or an alloy thereof. For example, the second sub-pad SPD2 may include, but is not limited to, copper (Cu).

The second pad electrode PDE2 may be located in the gate conductive layer GML. The second pad electrode PDE2 may include the same material as the gate conductive layer GML of the display area DA. For example, the second pad electrode PDE2 may include a single layer or a multilayer made of any one or more of molybdenum (Mo), aluminum (AI), chromium (Cr), gold (Au), titanium (Ti), nickel (Ni), neodymium (Nd), copper (Cu), or alloys thereof. In some embodiments, the second pad electrode PDE2 may include aluminum-zinc-tin-oxide (AZTO).

In some embodiments, the second pad electrode PDE2 may include a third sub-pad SPD3, a fourth sub-pad SPD4, a fifth sub-pad SPD5, and a sixth sub-pad SPD6.

The third sub-pad SPD3 may be located in the first gate conductive layer GML1. The third sub-pad SPD3 may include the same material as the first gate conductive layer GML1 of the display area DA. For example, the third sub-pad SPD3 may include molybdenum (Mo), aluminum (AI), chromium (Cr), gold (Au), titanium (Ti), nickel (Ni), neodymium (Nd), copper (Cu), or an alloy thereof. For example, the third sub-pad SPD3 may include, but is not limited to, titanium (Ti).

The fourth sub-pad SPD4 may be located in the second gate conductive layer GML2. The fourth sub-pad SPD4 may include the same material as the second gate conductive layer GML2 of the display area DA. For example, the fourth sub-pad SPD4 may include molybdenum (Mo), aluminum (AI), chromium (Cr), gold (Au), titanium (Ti), nickel (Ni), neodymium (Nd), copper (Cu), or an alloy thereof. For example, the fourth sub-pad SPD4 may include, but is not limited to, copper (Cu).

The fifth sub-pad SPD5 may be located in the third gate conductive layer GML3. The fifth sub-pad SPD5 may include the same material as the third gate conductive layer GML3 of the display area DA. For example, the fifth sub-pad SPD5 may include molybdenum (Mo), aluminum (AI), chromium (Cr), gold (Au), titanium (Ti), nickel (Ni), neodymium (Nd), copper (Cu), or an alloy thereof. For example, the fifth sub-pad SPD5 may include, but is not limited to, titanium (Ti).

The sixth sub-pad SPD6 may be located in the fourth gate conductive layer GML4. The sixth sub-pad SPD6 may include the same material as the fourth gate conductive layer GML4 of the display area DA. For example, the sixth sub-pad SPD6 may include transparent conductive oxide (TCO). For example, the sixth sub-pad SPD6 may include aluminum-zinc-tin-oxide (AZTO).

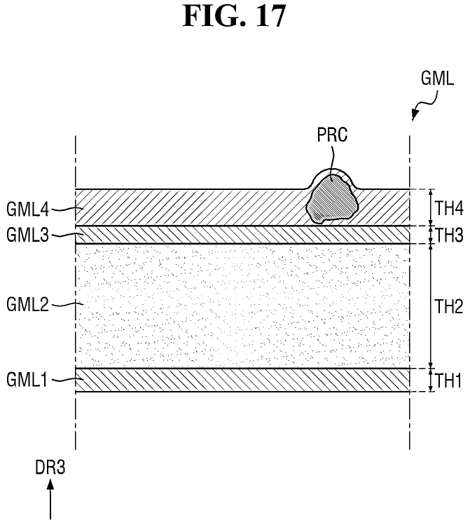

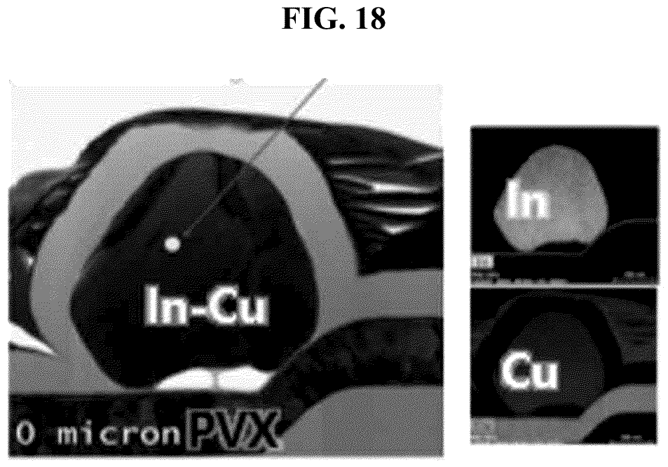

FIG. 17 is a cross-sectional view of an example of a conventional gate conductive layer GML. FIG. 18 is a photograph showing a precipitated particle formed on a cross section of the conventional gate conductive layer GML.

Referring to FIGS. 17 and 18 in addition to FIGS. 13 through 16, the gate conductive layer GML may not include indium. The conventional gate conductive layer GML may include indium. For example, a fourth gate conductive layer GML4 of the conventional gate conductive layer GML may include indium tin oxide (ITO). First through third gate conductive layers GML1 through GML3 of the conventional gate conductive layer GML may include the same materials as those of the gate conductive layer GML, respectively.

Referring to FIGS. 17 and 18, in the conventional gate conductive layer GML, because the fourth gate conductive layer GML includes indium, a precipitated particle PRC may be formed.

For example, if the third gate conductive layer GML3 includes titanium, then indium atoms of the fourth gate conductive layer GML4 may be precipitated in particle form due to a difference in binding energy (e.g., Gibbs free energy) between titanium oxide and indium oxide. Because titanium oxide has a lower Gibbs free energy than indium oxide, it may have a higher binding energy than indium oxide. Accordingly, oxygen atoms of indium-tin-oxide of the conventional fourth gate conductive layer GML4 may move toward titanium oxide due to high temperature generated in the process of forming a passivation layer PV or a via layer VIA on the gate conductive layer GML. Accordingly, the precipitated particle PRC may be formed in the fourth gate conductive layer GML.

Referring to FIG. 18, in a conventional display device 10, if the second gate conductive layer GML2 includes copper, if indium atoms are precipitated, indium atoms and copper atoms may be combined to produce an indium-copper alloy as the precipitated particle PRC.

Because the gate conductive layer GML does not include indium, the formation of the precipitated particle PRC including indium metal or indium-copper alloy can be avoided. Accordingly, the reliability of the gate conductive layer GML can be improved.

Hereinafter, first and second comparative examples and a first example will be compared and described with reference to Table 1 below. The first and second comparative examples may be the conventional gate conductive layer GML described above, and the first example may be the gate conductive layer GML described above.

TABLE 1

| | Structure of Gate | Reflectivity according to | | |
|---|---|---|---|---|
| | Conductive Layer | Wavelength of Light | | |
| Example | (1^{st}/2^{nd}/3^{rd}/4^{th} layers) | 450 nm | 550 nm | 650 nm |
| First | Ti/Cu/ITO | 35.4% | 22.3% | 62.7% |
| comparative | | | | |
| example | | | | |
| Second | Ti/Cu/Ti/ITO | 9.7% | 23.8% | 34% |
| comparative | | | | |
| example | | | | |
| First example | Ti/Cu/Ti/AZTO | 6.32% | 4.50% | 9.43% |

Referring to Table 1, a gate conductive layer GML according to the first comparative example may include a stacked structure of Ti/Cu/ITO, a gate conductive layer GML according to the second comparative example may include a stacked structure of Ti/Cu/Ti/ITO, and a gate conductive layer GML according to the first example may include a stacked structure of Ti/Cu/Ti/AZTO. In the stacked structure of Ti/Cu/ITO, the stacked structure of Ti/Cu/Ti/ITO, and the stacked structure of Ti/Cu/Ti/AZTO, the order from left to right indicates the order from a bottom layer to a top layer of a gate conductive layer GML.

Because the gate conductive layer GML according to the first comparative example does not include a Ti layer, the reflectivity reduction may hardly occur regardless of the wavelength of light.

Because the gate conductive layer GML according to the second comparative example includes a Ti layer, the reflectivity of the gate conductive layer GML according to the second comparative example for light having wavelengths of 450 nm and 650 nm may be lower than the reflectivity of the gate conductive layer GML according to the first comparative example for the light having the wavelengths of 450 nm and 650 nm. However, the reflectivity of the gate conductive layer GML according to the second comparative example for light having a wavelength of 550 nm may be higher than the reflectivity of the gate conductive layer GML according to the first comparative example for the light having the wavelength of 550 nm. In addition, because the gate conductive layer GML according to the second comparative example includes both a Ti layer and an ITO layer, the precipitated particle PRC may be formed as described above.

On the other hand, the gate conductive layer GML according to the first example may have lower reflectivity for light of all wavelengths than the gate conductive layers GML according to the first and second comparative examples. Because the gate conductive layer GML according to the first example includes a Ti layer and an AZTO layer, the reflectivity of the gate conductive layer GML can be reduced. In addition, because the gate conductive layer GML according to the first example does not include indium atoms, the precipitated particle PRC may not be formed, thus improving the reliability of the gate conductive layer GML.

Hereinafter, other embodiments of the display device 10 will be described. In the following embodiments, the same elements as those of the above-described embodiments are identified by the same reference characters, and any redundant description thereof will be omitted or given briefly, and differences will mainly be described.

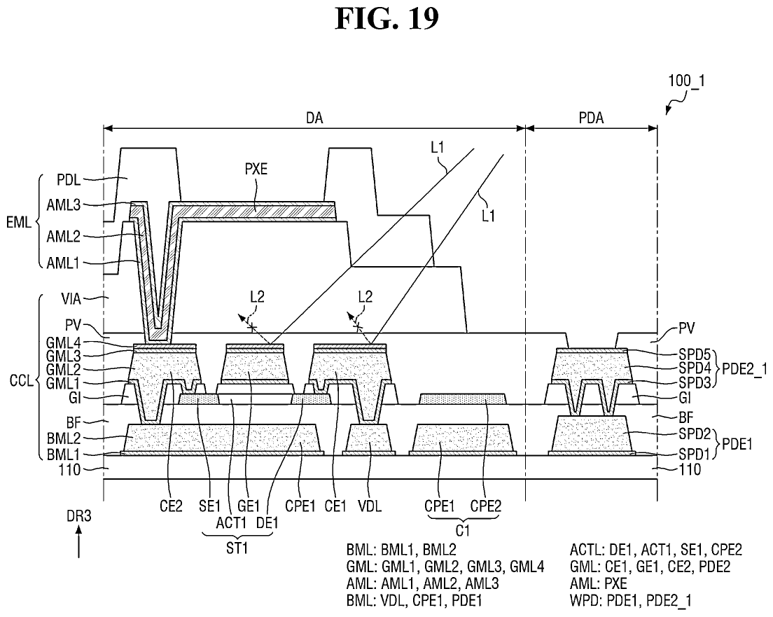

FIG. 19 is a cross-sectional view illustrating an example of a part of a display area DA and a part of a pad area PDA of a display device 10 according to one or more embodiments. FIG. 20 is a cross-sectional view illustrating a wiring pad WPD and a connection film 510 of the display device 10 according to one or more embodiments.

Referring to FIGS. 19 and 20, the display device 10 is different from the display device 10 described with reference to FIG. 13, etc., in that it does not include a sixth sub-pad SPD6.

For example, in a display substrate 100_1 of the display device 10, a second pad electrode PDE2_1 of the wiring pad WPD may not include the sixth sub-pad SPD6 (see FIG. 13). For example, an uppermost layer of the second pad electrode PDE2_1 of the wiring pad WPD may be a fifth sub-pad SPD5.

A passivation layer PV located on the wiring pad WPD may include a through hole for exposing the wiring pad WPD. The fifth sub-pad SPD5 may be exposed through the through hole of the passivation layer PV.

In some embodiments, the connection film 510 may include a base film 511 and a bump 512. The base film 511 may be a flexible circuit film on which components, such as a display driver 520 (see FIG. 4), can be mounted. The bump 512 may be a conductive protrusion protruding from the base film 511 toward the wiring pad WPD. In the display device 10, the bump 512 of the connection film 510 may directly contact the fifth sub-pad SPD5.

The sixth sub-pad SPD6 (see FIG. 13) of the display device 10 described with reference to FIG. 13, etc., may include metal oxide. On the other hand, the fifth sub-pad SPD5 of the display device 10 may include metal. Therefore, the wiring pad WPD of the display device 10 may have better electrical characteristics than the display device 10 described with reference to FIG. 13, etc. Accordingly, loss of signals and voltages that the display substrate 100_1 receives from the connection film 510, or provides to the connection film 510, can be reduced or minimized.

In the drawings, a case where the connection film 510 is connected to the wiring pad WPD is illustrated as an example. However, the present disclosure is not limited thereto. For example, the same technical spirit can be applied even if the display driver 520 (see FIG. 4) and/or the circuit board 530 (see FIG. 4) described with reference to FIGS. 4 and 5 are connected to the wiring pad WPD. Components connected to the wiring pad WPD, such as the connection film 510, the display driver 520 (see FIG. 4) and the circuit board 530 (see FIG. 4), may be referred to as driving components.

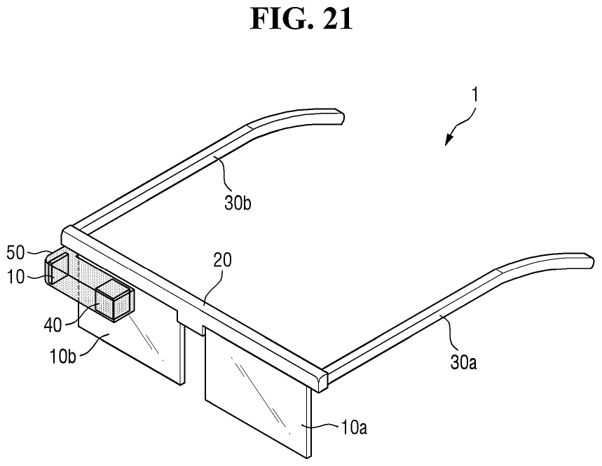

FIGS. 21 through 23 are schematic perspective views of devices including a display device according to one or more embodiments.

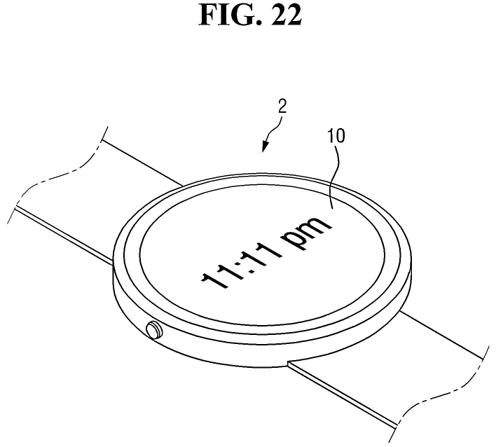

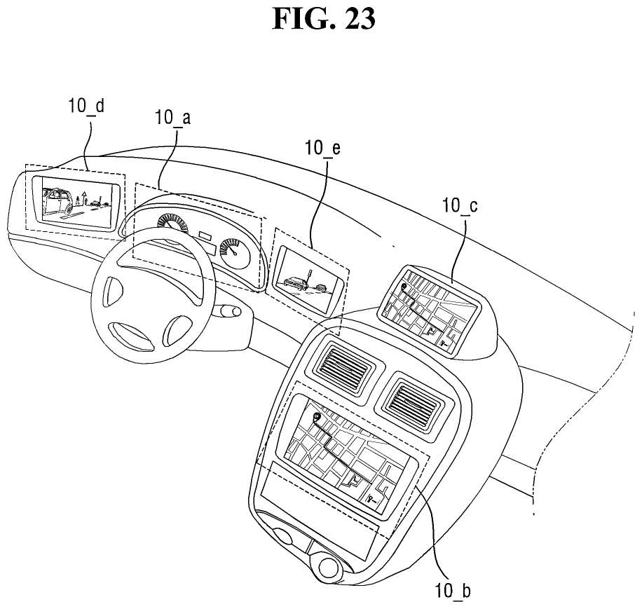

FIG. 21 illustrates a virtual reality (VR) device 1 to which a display device 10 according to one or more embodiments has been applied. FIG. 22 illustrates a smart watch 2 to which a display device 10 according to one or more embodiments has been applied. FIG. 23 illustrates display units of a vehicle to which display devices 10_a through 10_e according to one or more embodiments have been applied.

Referring to FIG. 21, the VR device 1 according to one or more embodiments may be a device in the form of glasses. The VR device 1 may include a display device 10, a left lens 10a, a right lens 10b, a support frame 20, eyeglass frame legs 30a and 30b, a reflective member 40, and a display device housing 50.

In the drawing, the VR device 1 including the eyeglass frame legs 30a and 30b is illustrated as an example. However, the VR device 1 can also be applied to a head-mounted display including a head-mounted band which can be worn on the head, instead of the eyeglass frame legs 30a and 30b. The VR device 1 is not limited to the illustrated structure and can be applied in various forms to various other electronic devices.

The display device housing 50 may include the display device 10 and the reflective member 40. An image displayed on the display device 10 may be reflected by the reflective member 40, and may be provided to a user's right eye through the right lens 10b. Accordingly, the user can view a VR image displayed on the display device 10 through the right eye.

The display device housing 50 may be located at a right end of the support frame 20. However, the present disclosure is not limited thereto. For example, the display device housing 50 may also be located at a left end of the support frame 20. In this case, an image displayed on the display device 10 may be reflected by the reflective member 40, and may be provided to the user's left eye through the left lens 10a. Accordingly, the user can view a VR image displayed on the display device 10 through the left eye. Alternatively, the display device housing 50 may be located at both the right end and the left end of the support frame 20. In this case, the user can view a VR image displayed on the display device 10 through both the left eye and the right eye.

Referring to FIG. 22, a display device 10 according to one or more embodiments may be applied to a smart watch 2 which is one of smart devices.

Referring to FIG. 23, display devices 10_a, 10_b, and 10_c according to one or more embodiments may be applied to a dashboard of a vehicle, a center fascia of the vehicle, or a center information display (CID) located on the dashboard of the vehicle. In addition, display devices 10_d and 10_e according to one or more embodiments may be applied to room mirror displays that replace side mirrors of the vehicle.

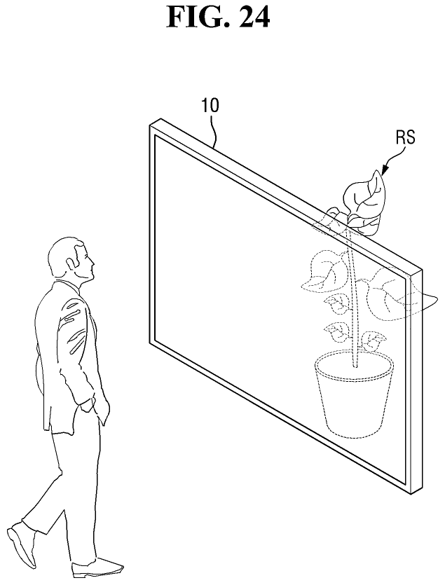

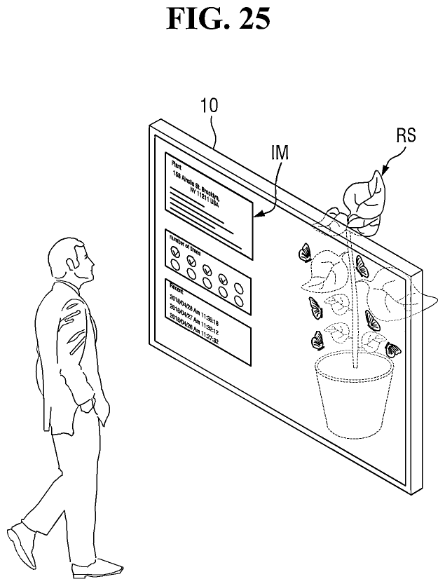

FIGS. 24 and 25 are schematic perspective views of a transparent display device including a display device 10 according to one or more embodiments.

Referring to FIGS. 24 and 25, the display device 10 may be applied to the transparent display device. The transparent display device may transmit light while displaying an image IM. A user located in front of the transparent display device can not only view the image IM displayed on the display device 10, but also can view an object RS or the background located behind the transparent display device.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a substrate;
a first conductive layer above the substrate;
an active layer above the first conductive layer;
a second conductive layer above the active layer, and comprising a transparent conductive oxide while not comprising indium (In);
a third conductive layer above the second conductive layer;
a transistor comprising a gate electrode at the second conductive layer, and a drain electrode and a source electrode at the active layer; and
a light-emitting element comprising a first electrode at the third conductive layer and connected to the source electrode.

2. The display device of claim 1, wherein the second conductive layer comprises aluminum-zinc-tin-oxide (AZTO).

3. The display device of claim 1, wherein the second conductive layer comprises a first gate conductive layer, and a second gate conductive layer above the first gate conductive layer and having higher light transmittance than the first gate conductive layer.

4. The display device of claim 3, wherein the second gate conductive layer comprises aluminum-zinc-tin-oxide (AZTO).

5. The display device of claim 4, wherein the second gate conductive layer comprises about 1 at % to about 10 at % of aluminum based on atoms excluding oxygen atoms.

6. The display device of claim 4, wherein the second gate conductive layer comprises about 60 at % to about 90 at % of zinc based on atoms excluding oxygen atoms.

7. The display device of claim 4, wherein the second gate conductive layer comprises about 10 at % to about 30 at % of tin based on atoms excluding oxygen atoms.

8. The display device of claim 4, wherein the second gate conductive layer comprises about 0.5 at % to about 5 at % of aluminum based on total atoms.

9. The display device of claim 4, wherein the second gate conductive layer comprises about 20 at % to about 40 at % of zinc based on total atoms.

10. The display device of claim 4, wherein the second gate conductive layer comprises about 7 at % to about 15 at % of tin based on total atoms.

11. The display device of claim 4, wherein the second gate conductive layer comprises about 50 at % to about 60 at % of oxygen based on total atoms.

12. The display device of claim 3, wherein the first gate conductive layer has lower reflectivity than the second gate conductive layer.

13. The display device of claim 12, wherein the first gate conductive layer comprises titanium (Ti).

14. The display device of claim 3, wherein a thickness of the second gate conductive layer is greater than a thickness of the first gate conductive layer.

15. The display device of claim 14, wherein the thickness of the second gate conductive layer is about 2 times to about 30 times the thickness of the first gate conductive layer.

16. The display device of claim 15, wherein the thickness of the second gate conductive layer is about 400 Å to about 3000 Å.

17. The display device of claim 15, wherein the thickness of the first gate conductive layer is about 100 Å to about 200 Å.

18. The display device of claim 1, wherein the third conductive layer comprises a transparent conductive oxide that is different from the transparent conductive oxide of the second conductive layer.

19. The display device of claim 1, wherein the second conductive layer has lower reflectivity than the first conductive layer or the third conductive layer.

20. A display device comprising:
a substrate;
a first conductive layer above the substrate;
an active layer above the first conductive layer;
a second conductive layer above the active layer, and comprising:
a first gate conductive layer comprising a first material comprising metal;
a second gate conductive layer above the first gate conductive layer, and comprising a second material comprising metal;
a third gate conductive layer above the second gate conductive layer, and comprising a third material comprising metal; and
a fourth gate conductive layer above the third gate conductive layer, and comprising aluminum-zinc-tin-oxide (AZTO);
a transistor above the first conductive layer; and
a light-emitting element above the second conductive layer and connected to the transistor.

21. The display device of claim 20, wherein the first material, the second material, and the third material comprise molybdenum (Mo), aluminum (AI), chromium (Cr), gold (Au), titanium (Ti), nickel (Ni), neodymium (Nd), copper (Cu), or an alloy thereof.

22. The display device of claim 21, wherein the first material comprises titanium (Ti).

23. The display device of claim 21, wherein the second material comprises copper (Cu).

24. The display device of claim 21, wherein the third material comprises titanium (Ti).

25. The display device of claim 20, wherein a thickness of the fourth gate conductive layer is greater than a thickness of the third gate conductive layer.

26. The display device of claim 20, wherein a thickness of the second gate conductive layer is greater than a thickness of the fourth gate conductive layer.

27. A display device comprising:
a substrate comprising a display area, and a pad area at a side of the display area;
a first conductive layer above the substrate;
an active layer above the first conductive layer;
a second conductive layer above the active layer, and comprising transparent conductive oxide, while not comprising indium (In), at the display area;
a transistor above the first conductive layer in the display area;
a light-emitting element above the second conductive layer in the display area, and connected to the transistor; and
a wiring pad above the substrate in the pad area, and comprising a first pad electrode at the first conductive layer, and a second pad electrode at the second conductive layer.

28. The display device of claim 27, wherein the second pad electrode does not comprise a transparent conductive oxide.

29. The display device of claim 27, further comprising a driving component connected to the wiring pad,
wherein the second pad electrode comprises a sub-pad layer comprising metal directly contacting the driving component.
